(19) United States
(12) Patent Application Publication
(10) Pub. No.: US 2026/0150484 A1
(43) Pub. Date: May 28, 2026

(54) LIGHT-EMITTING ELEMENT AND DISPLAY DEVICE

(71) Applicant: Sharp Display Technology Corporation, Kameyama City, Mie (JP)

(72) Inventors: Yuki FUKUNARI, Sakai City, Osaka (JP); TAKAYUKI NAKA, Sakai City, Osaka (JP); Kazuki MARUHASHI, Sakai City, Osaka (JP)

(21) Appl. No.: 19/120,443

(22) PCT Filed: Oct. 14, 2022
(86) PCT No.: PCT/JP2022/038464

§ 371 Date: Apr. 11, 2025

(51) Int. Cl. H10K 50/115

(52) U.S. Cl. CPC H10K 50/115

(57) ABSTRACT

A light-emitting element includes an anode a cathode, a light-emitting layer between the anode and the cathode, and an electron transport layer as an intervening layer between the light-emitting layer and the cathode. The light-emitting layer includes a plurality of quantum dots and an inorganic matrix material that fills spaces between the plurality of quantum dots. The electron transport layer includes at least one nanoparticle made of a first material including metal oxide, and a second material portion formed on at least part of a surface of the nanoparticle and made of an inorganic second material having an electron transport ability lower than that of the first material.

### TECHNICAL FIELD

The disclosure relates to a light-emitting element and a display device including the light-emitting element.

### BACKGROUND ART

PTL 1 discloses that Zn-containing metal oxide nanoparticles such as Zn₁₋ₓMgₓO (0<x≤0.5) obtained by alloying ZnO nanoparticles with Mg are used in an electron transport layer to increase the band gap of the ZnO nanoparticles and promote the electron injection. PTL 1 discloses that this makes it possible to obtain a light-emitting element having a higher luminous efficiency than a light-emitting element using the ZnO nanoparticles in the electron transport layer.

### CITATION LIST

### Patent Literature

PTL 1: KR 1020160033520 A

### SUMMARY

### Technical Problem

However, a light-emitting element including a layer made of an inorganic material between a cathode and a light-emitting layer generally has excessive electrons and poor carrier balance.

When a charge transport layer contains a metal ion or a hydroxide, carriers injected into the charge transport layer may be inactivated. The metal ion or hydroxide may oxidize and deactivate a light-emitting material in the light-emitting layer.

For example, a transport layer obtained by mixing two materials having different carrier mobilities or the like or two transport layers each containing a respective one of the two materials may be formed. In this case, there are problems such as damage to other layers in the process of forming the transport layer obtained by mixing the two materials, or an increase in a drive voltage due to an increase in the thickness of the light-emitting element by the formation of the two transport layers.

Furthermore, in manufacturing of the light-emitting layer of the light-emitting element in PTL 1, in order to improve the dispersibility of quantum dots in a solution, the quantum dots being materials of the light-emitting layer, organic ligands to be coordinated to the quantum dots may be added to the solution. In this case, the organic ligands remain in the light-emitting layer, and in the light-emitting element including the light-emitting layer containing the organic ligands, hopping conduction of the organic ligands is dominant in electron transport in the light-emitting layer during driving. Thus, in the light-emitting element, the electron injection into the light-emitting layer is excessive, and the excessive electrons in the light-emitting layer may worsen.

The excess of electrons in the light-emitting layer leads to deterioration of the light-emitting material of the light-emitting layer. Furthermore, the excess of electrons in the light-emitting layer may cause deterioration of each layer on an anode side of the light-emitting layer due to an outflow of electrons from the light-emitting layer to the anode side of the light-emitting element. Thus, the excess of electrons in the light-emitting layer may reduce the reliability and shorten the lifetime of the light-emitting element.

### Solution to Problem

A light-emitting element according to an aspect of the disclosure includes an anode, a cathode, a light-emitting layer between the anode and the cathode, and an intervening layer between the light-emitting layer and the cathode, in which the light-emitting layer includes a plurality of quantum dots and an inorganic matrix material that fills spaces between the plurality of quantum dots, and the intervening layer includes at least one nanoparticle made of a first material including a metal oxide, and a second material portion formed on at least part of a surface of the nanoparticle and made of an inorganic second material having an electron transport ability lower than that of the first material.

A light-emitting element according to another aspect of the disclosure includes an anode, a cathode, a light-emitting layer between the anode and the cathode; and an intervening layer between the light-emitting layer and the cathode, in which the light-emitting layer includes a plurality of quantum dots and an inorganic matrix material that fills spaces between the plurality of quantum dots, and the intervening layer includes at least one nanoparticle made of a first material including at least one selected from the group consisting of zinc oxide, magnesium zinc oxide, lithium zinc oxide, titanium oxide, and strontium titanium oxide, and a second material portion formed on at least part of a surface of the nanoparticle and made of a second material including at least one selected from the group consisting of magnesium oxide, zirconium oxide, aluminum oxide, yttrium oxide, silicon oxide, zinc sulfide, magnesium zinc sulfide, and strontium sulfide.

A light-emitting element according to another aspect of the disclosure includes an anode, a cathode, a light-emitting layer between the anode and the cathode, and an intervening layer between the light-emitting layer and the cathode, in which the light-emitting layer is formed by a method including synthesizing a quantum dot solution including a plurality of quantum dots and an inorganic precursor, applying the quantum dot solution, and filling spaces between the plurality of quantum dots with an inorganic matrix material by modifying the inorganic precursor into the inorganic matrix material in the applied quantum dot solution, and the intervening layer is formed by a method including synthesizing a first solution including at least one nanoparticle made of a first material, synthesizing a second solution by adding a second material different from the first material to the first solution, forming a second material portion made of the second material on at least part of a surface of the nanoparticle by an ultrasonic treatment on the second solution, and applying the second solution including at least one nanoparticle on which the second material portion is formed.

### Advantageous Effects of Disclosure

To implement a light-emitting element and a display device that can improve reliability by achieving both reduction in a drive voltage and improvement in carrier balance in a light-emitting layer while reducing damage to each layer in a manufacturing process.

### BRIEF DESCRIPTION OF DRAWINGS

FIG. 1 is views illustrating a schematic cross-sectional view of a light-emitting element according to a first embodiment, a schematic cross-sectional view of a nanoparticle structure, and a schematic view for illustrating an inorganic matrix material that fills a space between quantum dots, which are arranged side by side.

FIG. 2 is a schematic energy band diagram of each layer of the light-emitting element according to the first embodiment.

FIG. 3 is diagrams showing graphs showing relationships between an applied voltage and a current density in EOD according to each of an example and a comparative example and HOD according to each of the example and the comparative example, which are arranged side by side.

FIG. 4 is a flowchart for describing an example of a manufacturing method for the light-emitting element according to the first embodiment.

FIG. 5 is a flowchart for describing a method for forming the light-emitting layer according to the first embodiment.

FIG. 6 is a graph showing an example of X-ray diffraction spectra obtained by an X-ray diffraction measurement for a first solution and a second solution according to the first embodiment.

FIG. 7 is views illustrating a schematic cross-sectional view of a light-emitting element according to a second embodiment and a schematic cross-sectional view of a nanoparticle structure, which are arranged side by side.

FIG. 8 is a schematic cross-sectional view of a light-emitting element according to a third embodiment.

FIG. 9 is a schematic cross-sectional view of a display device according to a fourth embodiment.

FIG. 10 is a schematic energy band diagram of each layer of a red light-emitting element according to the fourth embodiment.

### DESCRIPTION OF EMBODIMENTS

### First Embodiment

### Light-Emitting Element: Outline

In the present embodiment, a charge injection type light-emitting element, in particular, a light-emitting element containing quantum dots as a light-emitting material in a light-emitting layer will be described as an example. However, the light-emitting element according to the present embodiment is not limited thereto, and may be, for example, an organic EL element (OLED element) containing an organic fluorescent material or an organic phosphorescent material in the light-emitting layer.

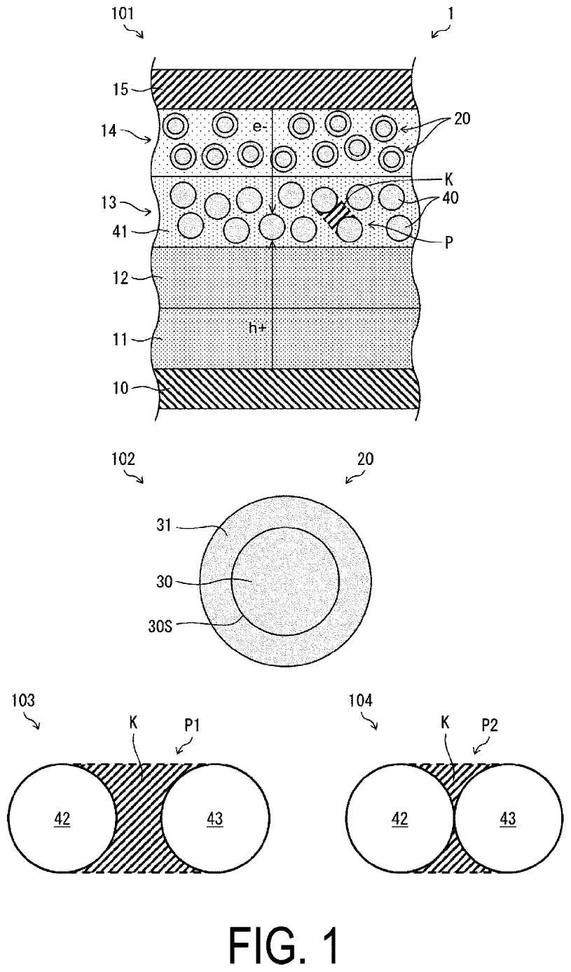

FIG. 1 is views illustrating a schematic cross-sectional view 101 of a light-emitting element 1 according to the present embodiment, a schematic cross-sectional view 102 of a nanoparticle structure 20 to be described later, and a schematic view 103 and a schematic view 104 each for illustrating an inorganic matrix material 41 that fills the space between quantum dots 40s to be described later, which are arranged side by side. The schematic cross-sectional view 101 of FIG. 1 illustrates a cross section of the light-emitting element 1 along a layering direction of each layer of the light-emitting element 1, and the schematic cross-sectional view 102 of FIG. 1 illustrates a cross section of the nanoparticle structure 20 passing through the center of a nanoparticle 30 to be described later in a simplified manner. The schematic views 103 and 104 of FIG. 1 are views each illustrating a respective one of two examples of a pair P of two quantum dots 40s and a region (space) K therebetween illustrated in the schematic cross-sectional view 101. In particular, the schematic views 103 and 104 are views illustrating pairs P1 and P2, respectively, which are examples of the pairs of a quantum dot 42 and a quantum dot 43.

As illustrated in the schematic cross-sectional view 101 of FIG. 1, the light-emitting element 1 includes an anode 10, a hole injection layer 11, a hole transport layer 12, a light-emitting layer 13, an electron transport layer 14, and a cathode 15 in this order from below. The light-emitting element 1 is not limited thereto, and a layering order of each layer may be reversed upside down. Specifically, the cathode 15, the electron transport layer 14, the light-emitting layer 13, the hole transport layer 12, the hole injection layer 11, and the anode 10 may be included in this order from below.

In the disclosure, for convenience of description of a manufacturing method and the like, “below or down” refers to a direction from each layer to a substrate. However, up and down are not necessarily fixed and up and down can be reversed as long as there is no contradiction.

### Light-Emitting Element: Anode and Cathode

The anode 10 and the cathode 15 are electrodes each containing a conductive material and are electrically connected to the hole injection layer 11 and the electron transport layer 14, respectively. When a voltage is applied to at least one of the anode 10 and the cathode 15, holes h⁺ and electrons e⁻ are injected from the anode 10 and the cathode 15 into the hole injection layer 11 and the electron transport layer 14, respectively.

At least one of the anode 10 and the cathode 15 is a transparent electrode through which visible light passes. As the transparent electrode, indium tin oxide (ITO), indium zinc oxide (IZO), SnO₂, or fluorine-doped tin oxide (FTO) may be used. One of the anode 10 and the cathode 15 may be a reflective electrode. The reflective electrode may contain a metal material having a high reflectance of visible light, and the metal material may be, for example, Al, Ag, Cu, or Au alone or an alloy thereof.

When the light-emitting element 1 is a top-emitting type in which light is extracted from the light-emitting layer 13 to be described later to the cathode 15 side, the anode 10 may be the reflective electrode and the cathode 15 may be the transparent electrode. On the other hand, when the light-emitting element 1 is a bottom-emitting type in which light is extracted from the light-emitting layer 13 to the anode 10 side, the anode 10 may be the transparent electrode and the cathode 15 may be the reflective electrode.

### Light-Emitting Element: Hole Injection Layer and Hole Transport Layer

The hole injection layer 11 is a layer that transports holes injected from the anode 10 to the hole transport layer 12. The hole transport layer 12 is a layer that transports the holes injected from the hole injection layer 11 to the light-emitting layer 13. As the material of the hole injection layer 11 and the hole transport layer 12, an organic or inorganic material having hole transport properties employed in related art in a light-emitting element containing quantum dots or the like can be used.

In particular, in the present embodiment, the hole injection layer 11 contains an inorganic material, and the hole transport layer 12 contains an organic material. As the inorganic material of the hole injection layer 11, MoO₃, NiO, MgNiO, or the like can be used. As the organic material of the hole transport layer 12, 4,4′, 4″-tris(9-carbazoyl)triphenylamine (TCTA), 4,4′-bis[N-(1-naphthyl)-N-phenyl-amino]-biphenyl (NPB), zinc phthalocyanine (ZnPC), di[4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), poly(N-vinylcarbazole) (PVK), poly(2,7-(9,9-di-n-octylfluorene)-(1,4-phenylene-((4-sec-butylphenyl)imino)-1,4-phenylene (TFB), N,N′-bis(4-butylphenyl)-N,N′-bis(phenyl)benzidine] (Poly-TPD), or the like can be used.

In general, among materials having hole transport properties, the organic material has a higher hole transport degree than the inorganic material. On the other hand, in general, among the materials having hole transport properties, the inorganic material has higher tolerability to foreign matters such as moisture, higher tolerability to heat, and higher reliability than the organic material. Thus, when the light-emitting element 1 includes the hole injection layer 11 containing the inorganic material and the hole transport layer 12 containing the organic material, the reliability can be improved while improving a luminous efficiency by increasing an efficiency of the hole transport.

However, the hole injection layer 11 may contain a complex of poly(3,4-ethylenedioxythiophene) (PEDOT) and poly(4-styrenesulfonic acid) (PSS), referred to as PEDOT:PSS, or the organic material such as the above-described HATCN. The hole transport layer 12 may contain a metal oxide such as NiO, MgNiO, LaNiO₃, CuO, Cu₂O, or MoO₃, or an inorganic material such as a material such as CuSCN in which a CN group, an SCN group, or an SeCN group is bonded to a metal.

When the hole injection layer 11 or the hole transport layer 12 contains the inorganic material, the hole injection layer 11 or the hole transport layer 12 may include a self assembled monolayer (SAM) film at an interface with another layer. In this case, since the hole injection layer 11 or the hole transport layer 12 efficiently transports holes via the SAM film, the drive voltage of the light-emitting element 1 is reduced.

### Light-Emitting Element: Electron Transport Layer

The electron transport layer 14 is a layer that transports electrons injected from the cathode 15 to the light-emitting layer 13. In the present embodiment, the electron transport layer 14 is an intervening layer containing an inorganic material having electron transport properties, and in particular, contains the nanoparticle structure 20 containing an inorganic material. In the disclosure, a layer between the light-emitting layer 13 and the cathode 15 is called the intervening layer. Hereinafter, a case in which the electron transport layer is provided as the intervening layer will be described as an example, but the disclosure is not limited thereto. For example, the light-emitting element may include an electron injection layer and an electron transport layer as the intervening layer, and may include the electron injection layer as the intervening layer according to the disclosure.

The nanoparticle structure 20 contained in the electron transport layer 14 will be described in detail with reference to the schematic cross-sectional view 102 of the nanoparticle structure 20 in FIG. 1. The nanoparticle structure 20 includes at least one nanoparticle 30 (first material portion, first portion) made of a first material to be described later, and a second material portion 31 (second portion) made of a second material to be described later and formed on at least part of a surface 30s of the nanoparticle 30.

In the disclosure, the “nanoparticle” refers to a dot (particle) made of a particle having a maximum width less than 1000 nm. A shape of the nanoparticle is not particularly limited as long as it is within a range in which having the above maximum width is satisfied, and the shape is not limited to a spherical three-dimensional shape (circular cross-sectional shape). The shape of the nanoparticle may be, for example, a polygonal cross-sectional shape, a rod-like three-dimensional shape, a branch-like three-dimensional shape, or a three-dimensional shape having unevenness on the surface thereof, or a combination thereof.

The first material contains a metal oxide having electron transport properties, and specifically contains at least one selected from the group consisting of zinc oxide, magnesium zinc oxide, lithium zinc oxide, titanium oxide, and strontium titanium oxide. The zinc oxide includes, for example, ZnO. The magnesium zinc oxide includes, for example, MgZnO. The lithium zinc oxide includes, for example, LiZnO. The titanium oxide includes, for example, TiO₂. The strontium titanium oxide includes, for example, strontium titanium oxide (SrTiO₃).

The second material is an inorganic material having an electron transport ability lower than that of the first material. In the present embodiment, the “electron transport ability” refers to an ability to transport electrons injected from another layer. For example, the second material has an electron mobility lower than that of the first material, in other words, has a low ability to transport electrons injected from another layer.

Specifically, the second material includes at least one selected from the group consisting of magnesium oxide, zirconium oxide, aluminum oxide, yttrium oxide, silicon oxide, zinc sulfide, magnesium zinc sulfide, and strontium sulfide. The magnesium oxide includes, for example, MgO. The zirconium oxide includes, for example, zirconia (ZrO₂). The aluminum oxide includes, for example, alumina (Al₂O₃). Yttrium oxide includes, for example, Y₂O₃. Silicon oxide includes, for example, silica (SiO₂) or silicon monoxide (SiO). Zinc sulfide includes, for example, ZnS. Magnesium zinc sulfide includes, for example, MgZnS. Strontium sulfide includes, for example, SrS. A composition represented by a chemical formula in the disclosure is desirably stoichiometric. However, other than stoichiometry is not excluded.

The electron transport layer 14 may contain, for example, a ligand as a dispersing agent added to improve dispersibility of the first material and the second material in a solution used for coating formation. In addition, the ligand may be contained in each layer of the light-emitting element 1 for various well-known reasons. Thus, it is not excluded that the ligand includes an organic or inorganic ligand together with the first material and the second material in each layer of the light-emitting element 1. The ligand may be capable of causing an interaction such as a coordination bond with the first material and the second material.

An analysis of the structure of the electron transport layer 14 can be performed by, for example, dividing the electron transport layer 14 in the layering direction of the light-emitting element 1 into thin pieces and observing the thin pieces with a transmission electron microscope (TEM) or the like. In particular, an elemental analysis of the electron transport layer 14 can be performed by performing the elemental analysis using energy dispersive X-ray spectroscopy (EDX), electron energy-loss spectroscopy (EELS), or the like of the thin piece. EELS is used when measurement cannot be performed by EDX.

For example, when a spectrum having a peak specific to the first material or the second material is obtained from a specific location in EDX or EELS of the thin piece described above, it may be determined that a member made of the first material or the second material is present at the location. Thus, for example, it is assumed to be confirmed that in the thin piece, at least part of the member containing the second material is formed on the outer periphery of the member containing the first material. In this case, it may be determined that the electron transport layer 14 contains the nanoparticle structure 20 including the nanoparticle 30 made of the first material and the second material portion 31 formed on the surface 30s of the nanoparticle 30. Here, the “outer periphery of the member” refers to a region in a range of 2 nm from an end portion of the member. That is, in order to confirm the nanoparticle structure 20, it may be confirmed that at least part of the member containing the second material is formed in the region in the range of 2 nm from at least part of the end portion of the member containing the first material. In other words, it may be confirmed that at least part of the member containing the second material is formed in at least part of the region in the range of the 2 nm from at least part of the end portion of the member containing the first material. Thus, the nanoparticle structure 20 including the nanoparticle 30 made of the first material and the second material portion 31 formed on at least part of the surface 30s of the nanoparticle 30 can be confirmed.

The thickness of the second material portion 31, in other words, the thickness from the surface 30s of the nanoparticle 30 to the outermost periphery of the nanoparticle structure 20 may be 0.4 nm or more and 2.0 nm or less or 0.4 nm or more and 1.0 nm or less. When the thickness of the second material portion 31 is 0.4 nm or more, the second material portion 31 can be more reliably formed on the surface 30s of the nanoparticle 30 by a method to be described later. In addition, when the thickness of the second material portion 31 is 2.0 nm or less, carriers can move by tunnel conduction, and when the thickness is 1.0 nm or less, an effect of reducing the drive voltage (power consumption) of the light-emitting element 1 to be described later can be more efficiently obtained. The thickness of the second material portion 31 may be measured by the above-described elemental analysis using EDX, EELS, or the like.

### Light-Emitting Element: Light-Emitting Layer: Quantum Dot

Referring back to the schematic cross-sectional view of the light-emitting element 1 illustrated in FIG. 1, the light-emitting layer 13 contains the quantum dots 40s as the light-emitting material and the inorganic matrix material 41 that fills the spaces between the quantum dots 40s. In the disclosure, the “quantum dot” is a particle having a maximum width of 100 nm or less. The shape of the quantum dot is not particularly limited as long as it is within a range satisfying the maximum width, and the shape is not limited to a spherical three-dimensional shape (circular cross-sectional shape). The shape of the nanoparticle may be, for example, a polygonal cross-sectional shape, a rod-like three-dimensional shape, a branch-like three-dimensional shape, or a three-dimensional shape having unevenness on the surface thereof, or a combination thereof.

The quantum dot 40 may be a quantum dot having a core/shell structure including, for example, a core and a shell formed around the core. In this case, the electrons and holes injected into the light-emitting layer 13 are recombined at the core of the quantum dot 40, so that light is obtained from the quantum dot 40. Since the light emitted from the quantum dot 40 has a narrower spectrum due to a quantum confinement effect, it is possible to obtain light emission with relatively deep chromaticity. The shell may have functions of suppressing generation of a defect, a dangling bond, or the like in the core and reducing recombination of carriers through a deactivation process. However, the quantum dot 40 is not limited to the above, and may have various structures known in the related art.

In particular, in the light-emitting layer 13 according to the present embodiment, a ratio of cadmium atoms in all atoms is 0.01 wt % or less. In other words, the ratio of cadmium atoms in the quantum dot 40 and the inorganic matrix material 41 is 0.01 wt % or less, or the quantum dot 40 and the inorganic matrix material 41 have no cadmium atoms. Thus, in the light-emitting element 1, the ratio of cadmium atoms in the quantum dot 40 and the inorganic matrix material 41 is equal to or less than the maximum tolerated concentration of the restriction of the use of certain hazardous substances in electrical equipment (RoHS) directive, and disposal processing or processing such as recycling of products including the light-emitting element 1 can be performed more simply.

However, the quantum dot 40 is not limited to the above and may be made of various materials known in the related art. For example, the quantum dot 40 may include InP/ZnS, ZnSe/ZnS, copper indium gallium selenide (CIGS)/ZnS, or the like as the core/shell structure. Note that the quantum dot may include the shell of a plurality of layers each containing a respective one of a plurality of materials different from each other.

The particle diameter of the quantum dot 40 is from about 1 nm to about 100 nm. A wavelength of the light emission from the quantum dot 40 can be controlled by the particle diameter of the quantum dot. In particular, when the quantum dot 40 has a core/shell structure, the wavelength of the light emission from the quantum dot 40 can be controlled by controlling the particle diameter of the core. Thus, the wavelength of the light emitted by the light-emitting element 1 may be controlled through the control of the particle diameter of the core the quantum dot 40.

### Light-Emitting Element: Light-Emitting Layer: Inorganic Matrix Material

The inorganic matrix material 41 is an inorganic material that fills the spaces between the plurality of quantum dots 40s contained in the light-emitting layer 13. In the disclosure, “the inorganic matrix material 41 fills the spaces between the plurality of quantum dots 40s” may be only necessary to know that the inorganic matrix material 41 fills at least a region K between the quantum dot 42 and the quantum dot 43, as illustrated in the schematic view 103 of the pair P1 illustrated in FIG. 1. In a cross-sectional view of the light-emitting layer 13, the region K is a region surrounded by two straight lines (external common tangent) in contact with the outer peripheries of the quantum dots 42 and 43 and the facing outer peripheries of the quantum dots 42 and 43. Thus, as illustrated in the schematic view 104 of the pair P2 illustrated in FIG. 1, the region K can exist even when the quantum dot 42 and the quantum dot 43 are close to each other, and the inorganic matrix material 41 fills the region K.

In addition, “the inorganic matrix material 41 fills the spaces between the plurality of quantum dots” does not necessarily mean that the region K between the quantum dot 42 and the quantum dot 43 is entirely made of only the inorganic matrix material 41. For example, a material such as an organic material different from the inorganic matrix material 41 may be included in the region K between the quantum dot 42 and the quantum dot 43. Specifically, for example, the light-emitting layer 13 may contain an organic ligand which is added to improve the dispersibility of the quantum dots in a solution used for coating formation and is coordinated to the outer peripheral surface of the quantum dot in the solution. In this case, in the light-emitting layer 13, as will be described later, for example, the weight ratio of the organic ligand to the total weight including the region K may be less than 5% from the viewpoint of improving the reliability of the light-emitting layer 13 and the luminous efficiency of the light-emitting element 1.

The inorganic matrix material 41 may fill a region other than the plurality of quantum dots in the light-emitting layer 13. For example, the outer edge (upper face and lower face) of the light-emitting layer 13 may be covered with the inorganic matrix material 41. Alternatively, a portion of the inorganic matrix material 41 may be located from the outer edge of the light-emitting layer 13, and the quantum dots may be located away from the outer edge. The outer edges of the light-emitting layer 13 need not be formed only by the inorganic matrix material 41, and part of the quantum dots may be exposed from the inorganic matrix material 41. The inorganic matrix material 41 may be indicated as a portion of the light-emitting layer 13 excluding the plurality of quantum dots.

The inorganic matrix material 41 may contain the plurality of quantum dots. The inorganic matrix material 41 may be formed so as to fill spaces formed between the plurality of quantum dots. The plurality of quantum dots may be embedded in the inorganic matrix material 41 at intervals.

The inorganic matrix material 41 may be a member that holds the spaces between the plurality of quantum dots, for example, between the quantum dot 42 and the quantum dot 43. In this case, the inorganic matrix material 41 is not necessarily limited to a case of completely filling the spaces between the plurality of quantum dots, but may partially have voids between the plurality of quantum dots, for example.

The inorganic matrix material 41 may include a continuous film having an area equal to or larger than 1000 nm² in a plane direction orthogonal to a film thickness direction. The continuous film may be a film that is not separated by a material other than a material constituting the continuous film in one plane. The continuous film may be in the form of an integrated film connected without interruption by chemical bonding of the inorganic matrix material 41.

The concentration of the inorganic matrix material 41 in the light-emitting layer 13 is, for example, an area ratio occupied by the inorganic matrix material 41 in a cross section of the light-emitting layer 13. This concentration may be 10% or more and 90% or less, or 30% or more and 70% or less in the cross-sectional observation. The concentration may be measured, for example, from an area ratio of an image obtained by the cross-sectional observation. When the quantum dot has a core-shell structure, the concentration of the shell may be 1% or more and 50% or less. The ratio of the core and the shell of the quantum dot, and the inorganic matrix material 41 may be adjusted so that the total is 100% or less as appropriate. When the shell and the inorganic matrix material 41 cannot be distinguished from each other, the shell may be regarded as part of the inorganic matrix material 41.

The material of the inorganic matrix material 41 may be the same as the material of the shell included in each of the plurality of quantum dots. In this case, an average distance between cores adjacent to each other (core-to-core distance) may be equal to or greater than 3 nm or may be equal to or greater than 5 nm. Alternatively, the average distance between cores adjacent to each other may be 0.5 times or more the average core diameter. The core-to-core distance is an average of shortest distances between adjacent cores in a space including 20 cores. The core-to-core distance may be kept wider than the distance when the shells are in contact with each other. The average core diameter is obtained by averaging the core diameters of 20 cores in the cross-sectional observation in a space including the adjacent 20 cores. The core diameter can be the diameter of a circle having the same area as the core area in the cross-sectional observation.

Unless otherwise specified or contradicted, the desired structure of the inorganic matrix material 41 need not be observed over the entire area of the light-emitting layer 13 as long as the desired structure is obtained by observing the cross section of the light-emitting layer 13 in the range of about 100 nm. The inorganic matrix material 41 may contain a substance different from the main material (for example, an inorganic substance such as an inorganic semiconductor), for example, as an additive.

The light-emitting layer 13 may be composed of the plurality of quantum dots 40 and the inorganic matrix material 41. The intensity of carbon detected by the chain structure of carbon when the light-emitting layer 13 is analyzed may be equal to or less than noise level. For example, when a quantum dot containing an organic ligand is used in the light-emitting layer 13, the carbon chain of the organic ligand may be decomposed or the organic ligand itself may be detached from the quantum dot during long-time driving. In this case, the quantum dot may be deteriorated and the luminance may be reduced. As in the disclosure, by filling the quantum dots 40s with the inorganic matrix material 41, the quantum dots 40s can be protected without using the organic ligand. Thus, the light-emitting element 1 according to the present embodiment can achieve high reliability, in other words, can achieve suppression of the reduction in luminance with respect to long-time driving of the light-emitting element 1.

In the present embodiment, the inorganic matrix material 41 has the same composition as, for example, the above-described second material.

### Light-Emitting Element: Band Gap of Light-Emitting Layer and Electron Transport Layer

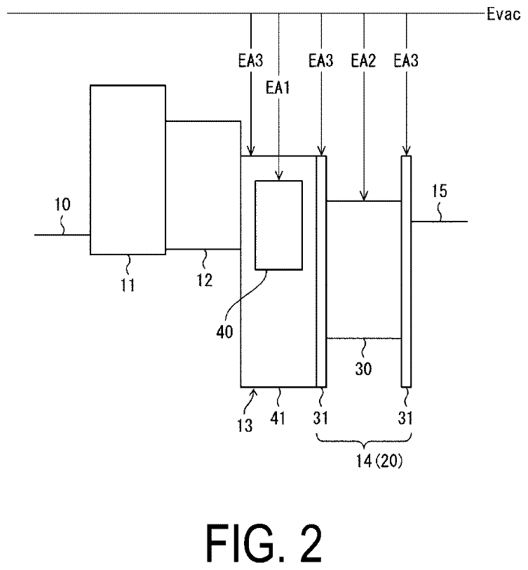

Effects of the light-emitting layer 13 and the electron transport layer 14 will now be described more in detail with reference to FIG. 2. FIG. 2 is a schematic energy band diagram of each layer of the light-emitting element 1 according to the present embodiment. In FIG. 2, the respective Fermi levels of the anode 10 and the cathode 15 are illustrated. FIG. 2 illustrates the band gaps of the hole injection layer 11, the hole transport layer 12, the light-emitting layer 13, and the electron transport layer 14.

In particular, FIG. 2 illustrates the band gaps of the quantum dot 40 and the inorganic matrix material 41 in the light-emitting layer 13. FIG. 2 illustrates the band gaps of the nanoparticle 30 made of the first material and the second material portion 31 made of the second material in the electron transport layer 14. Note that the energy band diagram of FIG. 2 illustrates the energy level of each layer with reference to a vacuum level Evac.

A barrier of the electron injection from the electron transport layer 14 into the quantum dot 40 of the light-emitting layer 13 will be considered with reference to FIG. 2. Here, an electron affinity of the quantum dot 40 is EA1, an electron affinity of the nanoparticle 30 of the electron transport layer 14 is EA2, and an electron affinity of the second material portion 31 is EA3.

As illustrated in FIG. 2, in the present embodiment, the electron affinity EA1 of the quantum dot 40 of the light-emitting layer 13 is smaller than the electron affinity EA2 of the nanoparticle 30 of the electron transport layer 14, and is larger than the electron affinity EA3 of the second material portion 31. This corresponds to the fact that, in FIG. 2, an upper end of the band gap of the quantum dot 40 is higher than an upper end of the band gap of the nanoparticle 30 of the electron transport layer 14 and lower than an upper end of the band gap of the second material portion 31 of the electron transport layer 14.

However, it is assumed that various materials are used for the electron affinity EA3 of the second material portion 31, and the electron affinity EA1 of the quantum dot 40 may be smaller than the electron affinity EA3 of the second material portion 31. Hereinafter, a case where the electron affinity EA1 of the quantum dot 40 is larger than the electron affinity EA3 of the second material portion 31 will be described.

In the present embodiment, the inorganic matrix material 41 has the same composition as the second material of the second material portion 31. Thus, the band gap of the inorganic matrix material 41 and the band gap of the second material portion 31 substantially coincide with each other, and the electron affinity of the inorganic matrix material 41 is EA3. Thus, the electron affinity EA1 of the quantum dot 40 is larger than the electron affinity EA3 of the inorganic matrix material 41. This corresponds to the fact that the upper end of the band gap of the quantum dot 40 is lower than the upper end of the band gap of the inorganic matrix material 41 in FIG. 2.

The electron affinity EA1 of the quantum dot 40 is represented by an absolute value of an energy difference between the vacuum level Evac and the lower end (CBM) of a conduction band of the quantum dot 40. The electron affinity EA2 of the nanoparticle 30 of the electron transport layer 14 is represented by an absolute value of an energy difference between the vacuum level Evac and the CBM of the nanoparticle 30 of the electron transport layer 14. The electron affinity EA3 of the second material portion 31 of the electron transport layer 14 and the inorganic matrix material 41 is represented by an absolute value of an energy difference between the vacuum level Evac and the CBM of the second material portion 31 of the electron transport layer 14 or the inorganic matrix material 41.

The electron affinity of the second material is smaller than the electron affinity of the first material. Thus, the electron affinity EA3 of the second material portion 31 and the inorganic matrix material 41 is smaller than the electron affinity EA2 of the nanoparticle 30 of the electron transport layer 14.

In general, in a charge injection type light-emitting element, the height of a barrier when electrons are injected from a first layer into a second layer adjacent to the first layer is represented by an energy difference between the CBM of the first layer and the CBM of the second layer. In particular, a barrier of the electron injection from the first layer into the second layer corresponds to an energy obtained by subtracting the electron affinity of the second layer from the electron affinity of the first layer.

An energy obtained by subtracting the electron affinity EA3 from the electron affinity EA1 is smaller than an energy obtained by subtracting the electron affinity EA2 from the electron affinity EA1. Thus, a barrier of the electron injection from the second material portion 31 or the inorganic matrix material 41 into the quantum dot 40 is smaller than a barrier of the electron injection from the nanoparticle 30 into the quantum dot 40.

When the electron transport layer 14 contains only the nanoparticle 30 and the light-emitting layer 13 contains only the quantum dot 40, injection of electrons from the electron transport layer 14 into the light-emitting layer 13 is achieved by the electron injection from the nanoparticle 30 into the quantum dot 40. In this case, the barrier of the electron injection from the nanoparticle 30 into the quantum dot 40 corresponds to the energy obtained by subtracting the electron affinity EA2 from the electron affinity EA1.

On the other hand, as in the light-emitting element 1 according to the present embodiment, the electron transport layer 14 contains the nanoparticle 30 and the second material portion 31, or further the light-emitting layer 13 contains the quantum dot 40 and the inorganic matrix material 41. In this case, in the injection of electrons from the electron transport layer 14 into the light-emitting layer 13, a process of the electron injection from the second material portion 31 into the quantum dot 40 or a process of the electron injection from the second material portion 31 into the quantum dot 40 via the inorganic matrix material 41 occurs. In this process, a barrier of the electron injection from the second material portion 31 or the inorganic matrix material 41 into the quantum dot 40 corresponds to the energy obtained by subtracting the electron affinity EA3 from the electron affinity EA1, and is smaller than the energy obtained by subtracting the electron affinity EA2 from the electron affinity EA1. In the present embodiment, since the energy is negative, an injection process occurs in which a substantial barrier does not occur.

Thus, since the electron transport layer 14 contains the nanoparticle 30 and the second material portion 31, a barrier of the electron injection from the electron transport layer 14 into the quantum dot 40 can be reduced. In addition, since the light-emitting layer 13 contains the inorganic matrix material 41 including the second material, a barrier of the electron injection from the nanoparticle 30 into the quantum dot 40 via the second material portion 31 and the inorganic matrix material 41 can be reduced.

Furthermore, the inorganic matrix material 41 has the same composition as the second material of the second material portion 31. Thus, the light-emitting layer 13 suppresses the formation of a dangling bond or an interface state at an interface between the inorganic matrix material 41 and the electron transport layer 14, in particular, at an interface between the inorganic matrix material 41 and the second material portion 31.

Thus, the light-emitting element 1 reduces the resistance at the interface between the electron transport layer 14 and the inorganic matrix material 41.

Thus, since the light-emitting element 1 achieves the transport of electrons from the cathode 15 to the light-emitting layer 13 at a lower applied voltage by the light-emitting layer 13 and the electron transport layer 14, the light-emitting element 1 can reduce the drive voltage of the light-emitting element 1.

In general, electron injection properties are improved by reduction of the barrier of the electron injection. However, as described above, the second material has the electron transport ability lower than that of the first material. Thus, the efficiency of the electron transport from the cathode 15 to the light-emitting layer 13 via the electron transport layer 14 is lower than that in the case where the electron transport layer 14 contains only the nanoparticle 30. Thus, the light-emitting element 1 can reduce the excessive electrons in the light-emitting layer 13 by reducing an electron density in the light-emitting layer 13 and can improve the carrier balance of the light-emitting layer 13. Thus, according to the present embodiment, it is possible to achieve reduction of the drive voltage and suppression of the electron injection at the same time by the second material having the electron transport ability lower than that of the first material.

As described above, the light-emitting element 1 can improve the carrier balance in the light-emitting layer 13 while reducing the drive voltage by the electron transport layer 14.

In the light-emitting element 1, since there is a barrier of the electron injection from the light-emitting layer 13 into the hole transport layer 12, accumulation of electrons may occur mainly between the light-emitting layer 13 and the hole transport layer 12. In general, when the accumulation of electrons occurs in a light-emitting layer of a light-emitting element, the efficiency of recombination of holes and electrons may be reduced, or a temporary reduction in luminous efficiency and deterioration of each layer of the light-emitting element may occur due to generation of Auger electrons due to interaction between electrons. In order to eliminate the accumulation of electrons and recover the luminous efficiency of the light-emitting element, it is necessary to stop driving the light-emitting element until the accumulated electrons are naturally emitted from the light-emitting layer.

The light-emitting element 1 according to the present embodiment can suppress the accumulation of electrons between the light-emitting layer 13 and the hole transport layer 12 in order to achieve suppression of the electron injection from the electron transport layer 14 into the light-emitting layer 13. Thus, the light-emitting element 1 can reduce the above-described temporary reduction in luminous efficiency and deterioration of each layer of the light-emitting element 1. In addition, the light-emitting element 1 can release the accumulated electrons and reduce the stop time of the driving of the light-emitting element 1, which is required to recover luminous efficiency described above.

### Light-Emitting Element: Effects of Inorganic Matrix Material of Light-Emitting Layer

Furthermore, as described above, the light-emitting layer 13 contains the inorganic matrix material 41 that fills the spaces between the plurality of quantum dots 40s. For the reason to be described later, the light-emitting layer 13 containing the inorganic matrix material 41 reduces the electron injection and reduces the excessive electrons in the light-emitting layer as compared with a case where an organic material such as an organic ligand is contained. In the disclosure, the reason will be described through measurement of physical properties of an electron-only device (EOD) according to each of an example and a comparative example and a hole-only device (HOD) according to each of the example and the comparative example.

In the example, the following EOD and HOD were prepared and a current density with respect to an applied voltage was measured. The EOD according to the example was prepared by layering an indium-tin oxide (ITO) electrode as an anode, the above-described light-emitting layer 13, a layer of magnesium zinc oxide, and an Al electrode as a cathode in this order. The HOD according to the example was prepared by layering an ITO electrode as an anode, a layer of nanoparticles of nickel oxide, a self assemble monolayer (SAM) film, the above-described light-emitting layer 13, a layer of molybdenum oxide, and an Ag electrode as a cathode in this order.

Each of the EOD and the HOD according to the comparative example was prepared to have the same configuration as the EOD and the HOD according to the above-described example except for the light-emitting layer 13. Each of the EOD and the HOD according to the comparative example includes, instead of the light-emitting layer 13, a light-emitting layer that does not contain the inorganic matrix material 41 and contains the quantum dot 40 to which the organic ligand is coordinated.

When a voltage is applied between the electrodes of the above-described EOD, electrons out of electrons and holes predominantly flow in the light-emitting layer of the EOD. Thus, by measuring the current density with respect to the applied voltage in the EOD, the efficiency of the electron injection in the light-emitting layer of the EOD can be measured. On the other hand, when a voltage is applied between the electrodes of the above-described HOD, holes out of electrons and holes dominantly flow in the light-emitting layer of the HOD. Thus, by measuring the current density with respect to the applied voltage in the HOD, the efficiency of the hole injection in the light-emitting layer of the HOD can be measured.

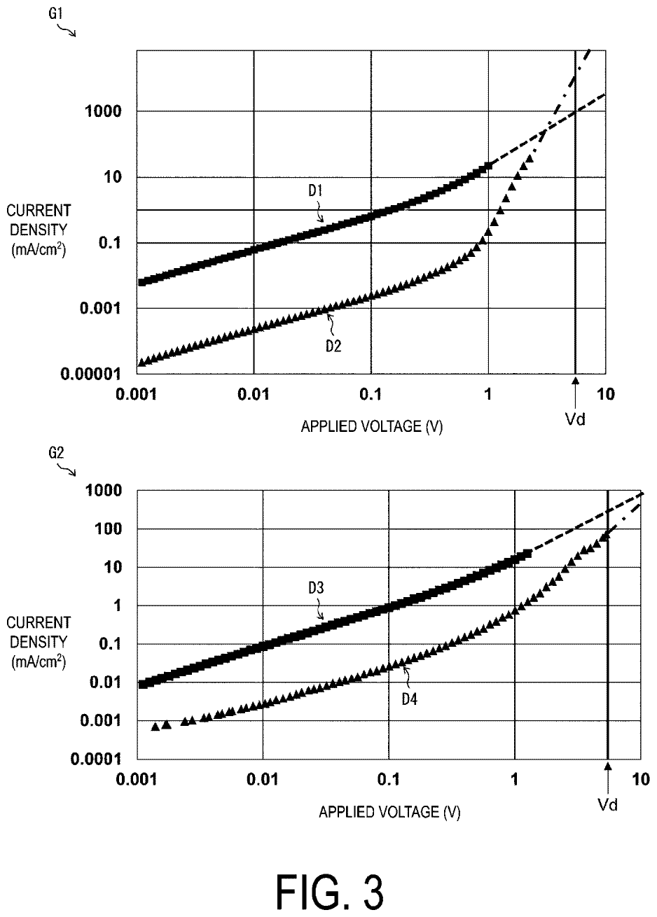

A voltage was applied to the EOD and the HOD according to each of the fabricated example and comparative example, and the current density with respect to the applied voltage was measured. The measurement results are summarized in the graphs in FIG. 3. FIG. 3 is diagrams showing graphs showing relationships between an applied voltage and a current density in EOD according to each of an example and a comparative example and HOD according to each of the example and the comparative example, which are arranged side by side.

The graph G1 in FIG. 3 shows the measurement results of the current density with respect to the applied voltage in the EOD according to each of the example and the comparative example. The graph G2 in FIG. 3 shows the measurement results of the current density with respect to the applied voltage in the HOD according to each of the example and the comparative example. In the graph G1 and the graph G2, the horizontal axis represents the applied voltage (unit: V), and the vertical axis represents the current density (unit: mA/cm²). In the graphs G1 and G2, a normal drive voltage Vd, which is a mean value of a voltage applied to the light-emitting element 1 when the light-emitting element 1 according to the present embodiment is normally used, is indicated by a solid line. The normal drive voltage Vd is, for example, about 6V.

The data D1 in the graph G1 are the measurement result in the EOD according to the example, and the data D2 in the graph G1 are the measurement result in the EOD according to the comparative example. The data D3 in the graph G2 are the measurement result in the HOD according to the example, and the date D4 in the graph G2 is the measurement result in the HOD according to the comparative example. Note that the interpolated data at the applied voltage of 1 V or greater are indicated by a dotted line in the data D1 and the data D3 and by a one dot chain line in the data D2 and the data D4.

As shown in the graph G1, when driven at a low voltage of less than 1 V, the current density of the EOD according to the example is higher than the current density of the EOD according to the comparative example. However, when driven at 1 V or more, the current density of the EOD according to the comparative example rapidly increases with respect to an increase in the drive voltage. It is conceivable to be because the hopping conduction of the organic ligand is dominant in the transport of electrons in the light-emitting layer of the EOD according to the comparative example. On the other hand, even when driven at 1 V or more, the increase in the current density with respect to the increase in the drive voltage of the EOD according to the example is suppressed as compared with the case of the EOD according to the comparative example. it is conceivable to be due to the fact that the light-emitting layer of the EOD according to the example contains almost no organic ligand that allows hopping conduction of electrons. Thus, as shown in the graph G1, in the vicinity of the normal drive voltage Vd, the current density of the EOD according to the example is lower than the current density of the EOD according to the comparative example.

Thus, according to the data indicated in the graph G1, in the vicinity of the normal drive voltage Vd, the efficiency of the electron injection into the light-emitting layer 13 in the light-emitting element 1 including the light-emitting layer 13 is reduced as compared with the efficiency of the electron injection into the light-emitting layer in the light-emitting element including the light-emitting layer containing the organic ligand.

On the other hand, as shown in the graph G2, when driven at the low voltage less than 1 V, the current density of the HOD according to the example is higher than the current density of the HOD according to the comparative example. In addition, even when driven at 1 V or more, there is little difference between degrees of increase in the current density with respect to the increase in the drive voltage of the HOD according to the example and the comparative example. it is conceivable to be because the contribution of the above-described hopping conduction in the light-emitting layer to the hole transport is smaller than the contribution thereof to the electron transport. Thus, as shown in the graph G2, also in the vicinity of the normal drive voltage Vd, the current density of the HOD according to the example is higher than the current density of the HOD according to the comparative example.

Thus, according to the data indicated in the graph G2, in the vicinity of the normal drive voltage Vd, the efficiency of the hole injection into the light-emitting layer 13 in the light-emitting element 1 including the light-emitting layer 13 is improved as compared with the efficiency of the hole injection into the light-emitting layer in the light-emitting element including the light-emitting layer containing the organic ligand.

As described above, since the light-emitting layer 13 according to the present embodiment contains the inorganic matrix material 41, the light-emitting layer 13 improves the efficiency of the hole injection into the light-emitting layer 13 while suppressing the efficiency of the electron injection as compared with the light-emitting layer that does not contain the inorganic matrix material 41 and contains the organic ligand. Thus, the light-emitting element 1 according to the present embodiment more efficiently reduces the excessive electrons in the light-emitting layer 13, thereby achieving the improvement in the luminous efficiency and the reliability.

When the light-emitting element 1 includes the light-emitting layer 13, since the efficiency of the electron injection is improved in accordance with the improvement in the efficiency of the hole injection as compared with the case where the light-emitting element 1 includes the light-emitting layer not containing the inorganic matrix material 41. the above-described accumulation of electrons in the light-emitting element 1 may increase. However, as described above, in the light-emitting element 1 according to the present embodiment, the accumulation of electrons in the light-emitting element 1 can be suppressed in order to achieve suppression of the electron injection from the electron transport layer 14 into the light-emitting layer 13. Thus, since the light-emitting element 1 includes both the light-emitting layer 13 and the electron transport layer 14, the light-emitting element 1 can efficiently suppress the excessive electrons in the light-emitting layer 13 while reducing the drive voltage and achieve both reduction of the drive voltage and improvement in the luminous efficiency and reliability.

### Manufacturing Method for Light-Emitting Element: up to Formation of Light-Emitting Layer

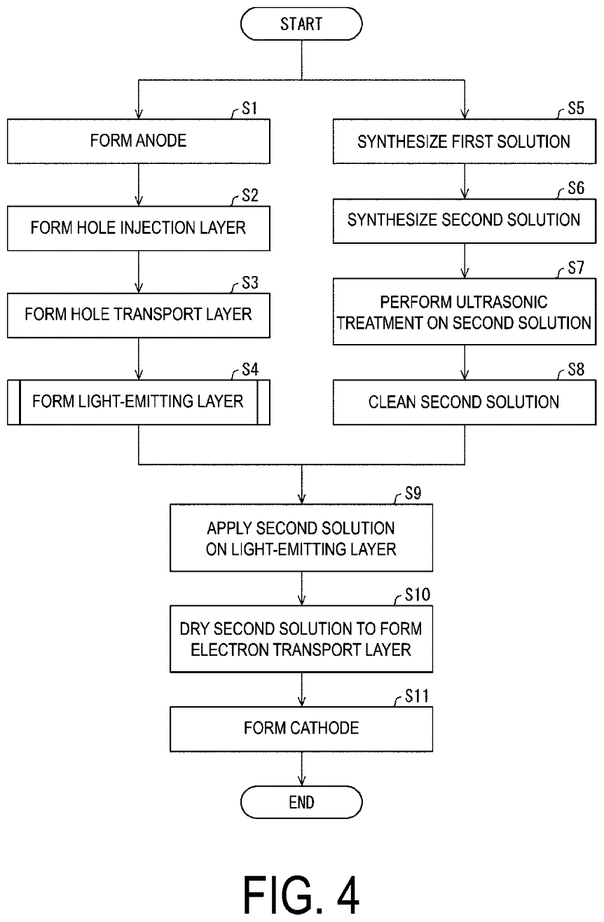

A manufacturing method for the light-emitting element 1 according to the present embodiment will be described with reference to FIG. 4. FIG. 4 is a flowchart illustrating an example of the manufacturing method for the light-emitting element 1.

In the manufacturing method for the light-emitting element 1 according to the present embodiment, first, the anode 10 is formed (step S1). The anode 10 may be formed by, for example, depositing a conductive material on a substrate by sputtering or the like. Specifically, the anode 10 may be formed by, for example, depositing a thin film of ITO having a film thickness of 30 nm and a size of 2 mm×10 mm on the substrate by sputtering.

Next, the hole injection layer 11 is formed (step S2). The hole injection layer 11 may be formed on the anode 10 by, for example, a coating formation method such as a spin coating method using a colloidal solution, or may be formed by a vacuum vapor deposition technique, sputtering, or the like. Specifically, a thin film may be formed by, for example, applying nickel oxide having a particle diameter of 10 nm onto the anode 10 by spin coating and drying nickel oxide. Furthermore, the hole injection layer 11 may be formed by bringing the thin film into contact with a solution in which MeO-2PACz is dissolved in ethanol to a concentration of 0.01 M for 5 seconds or more and drying the thin film.

Next, the hole transport layer 12 is formed (step S3). The hole transport layer 12 may be formed on the hole injection layer 11 by, for example, a coating formation method such as a spin coating method using a colloidal solution, or may be formed by a vacuum vapor deposition technique, sputtering, or the like. Specifically, the hole transport layer 12 may be formed by, for example, applying a solution in which 8 mg of Poly-TPD is dissolved in chlorobenzene of 1 ml onto the hole injection layer 11 by spin coating method drying the solution.

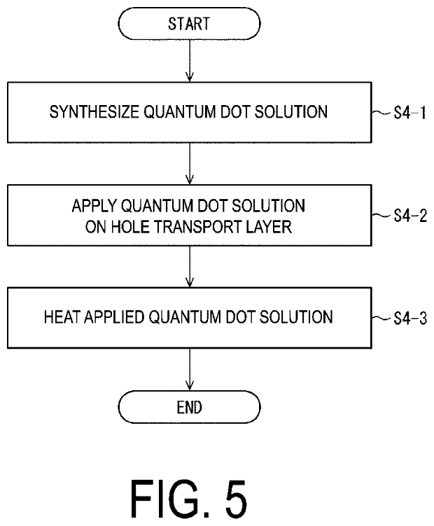

Next, the light-emitting layer 13 is formed (step S4). A detailed method for forming the light-emitting layer 13 will now be further described with reference to FIG. 5. FIG. 5 is a flowchart illustrating an example of a method for forming the light-emitting layer 13.

In a forming process of the light-emitting layer 13, first, a quantum dot solution containing the quantum dots 40s and inorganic precursors which are precursors of the inorganic matrix material 41 is synthesized (step S4-1). In step S4-1, the quantum dot solution may be synthesized by, for example, synthesizing the quantum dots 40s in a solvent such as N, N-dimethylformamide (DMF) and adding the inorganic precursors to the solvent.

The quantum dots 40s may be synthesized by various methods known in the related art. The quantum dot 40 may be synthesized by, for example, adding a material to the solvent, synthesizing a core by crystal growth in the solvent, and synthesizing a shell by crystal growth on the surface of the core. In addition to the inorganic precursors, organic ligands for maintaining the dispersibility of the quantum dots 40s in the solution may be added to the quantum dot solution.

Next, the quantum dot solution synthesized in step S4-1 is applied onto the hole transport layer 12 (step S4-2). The application of the quantum dot solution may be performed by various application methods such as a spin coating method and an ink-jet method.

Next, the quantum dot solution applied in step S4-2 is heated (step S4-3). In step S4-3, for example, each layer on the anode 10 including the quantum dot solution is heated in an atmosphere of 200° C. for 30 minutes. Thus, the inorganic precursors in the quantum dot solution are modified to form the inorganic matrix material 41. Here, the inorganic precursors in the quantum dot solution are modified by the heating in step S4-3, and the inorganic matrix material 41 is sequentially formed around the quantum dot 40 in the quantum dot solution. Accordingly, in step S4-3, the inorganic matrix material 41 is formed so as to fill the spaces between the plurality of quantum dots 40s.

Thus, the light-emitting layer 13 containing the plurality of quantum dots 40s and the inorganic matrix material 41 that fills the spaces between the quantum dots 40s is formed, and step S4 is completed. When the quantum dot solution contains the organic ligands, the organic ligands may be volatilized from the quantum dot solution by heating in step S4-3 so that a weight ratio of the organic ligands in the light-emitting layer 13 is less than 5%.

### Manufacturing Method for Light-Emitting Element: Synthesis of Solution of Electron Transport Material

In the manufacturing method for the light-emitting element 1, the electron transport layer 14 is formed after the formation of the light-emitting layer 13. In the present embodiment, the electron transport layer 14 is formed by a coating formation method using a solution containing the nanoparticle structures 20s as described later. Here, in the manufacturing method for the light-emitting element 1, the solution used in the coating formation method is synthesized before the coating formation method is performed.

Specifically, in the manufacturing method for the light-emitting element 1, a first solution containing the nanoparticles 30s is synthesized (step S5). The first solution may be synthesized by, for example, adding precursors of the nanoparticles 30s each containing the first material to a solvent such as ethanol and stirring the mixture.

More specifically, in step S5, first, a solution in which zinc acetate dihydrate and magnesium acetate tetrahydrate are dissolved in dimethylsulfoxide at a molar ratio of 85:15 is synthesized. Next, by adding a solution obtained by dissolving tetramethylammonium hydroxide in ethanol to the solution and stirring the solution for 1 hour, the first solution in which the nanoparticles 30s each containing zinc oxide are dispersed may be synthesized.

Next, a second solution in which the above-described second material is added to the first solution is synthesized (step S6). Specifically, the second solution may be synthesized by adding magnesium acetate tetrahydrate to the first solution in an amount of 30 mol % with respect to solutes in the first solution.

Next, an ultrasonic treatment is performed on the second solution (step S7). The second solution is subjected to a rapid and short-term heat treatment by the ultrasonic treatment. The second material is formed on the surface 30s of the nanoparticle 30 in the second solution by the heat treatment. Thus, the second material portion 31 containing the second material is formed on the surface 30s of the nanoparticle 30 in the second solvent, in other words, the nanoparticle structure 20 is synthesized in the second solution.

Next, the second solution is cleaned (step S8). The cleaning of the second solution is performed by removing the first material or the second material not contained in the nanoparticle structure 20 from the second solution by, for example, adding an appropriate solvent to the second solution and centrifuging the second solution. As described above, the synthesis of the second solution used in the coating formation method of the electron transport layer 14 is completed. The second solution may be allowed to stand for an appropriate period between step S7 and step S8.

### Manufacturing Method for Light-Emitting Element: Element Identification of Solution

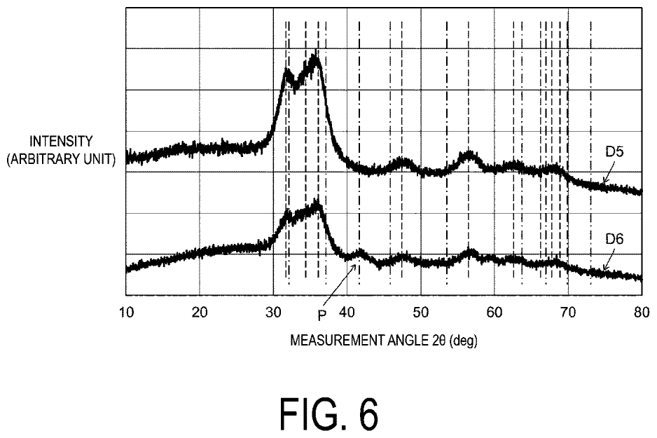

The elements contained in the first solution and the second solution synthesized by the above-described method may be confirmed by element identification for each solution using X-ray diffraction (XRD, X-ray diffractometer). A method of the element identification using XRD will be described with reference to FIG. 6.

FIG. 6 is a graph showing the results of X-ray diffraction spectrum measurement for each of the first solution and the second solution synthesized by the above-described method. In the graph in FIG. 6, the horizontal axis represents the measurement angle 2θ (unit:deg) which is twice the incident angle (reflection angle) of the X-ray with respect to the measurement target, and the vertical axis represents the intensity (arbitrary unit) of the measured X-ray.

In the present embodiment, an X-ray diffraction spectrum measurement using XRD was performed on a thin film obtained by dropping and drying the first solution synthesized in the above-described step S5 on a substrate, and spectral data D5 shown in FIG. 6 was obtained. In addition, the X-ray diffraction spectrum measurement using XRD was performed on a thin film obtained by dropping and drying the second solution synthesized in the above-described steps S6 to S8 on a substrate, and spectral data D6 shown in FIG. 6 was obtained. In order to facilitate comparison of the two, the intensities of the two spectral data in FIG. 6 are offset.

In FIG. 6, a reference of zinc oxide is indicated by broken lines, and a reference of magnesium oxide is indicated by one dot chain lines. In other words, when zinc oxide is contained in a sample measured by XRD, a peak is mainly observed at measurement angles indicated by the broken lines in the spectral data obtained by the measurement. When the sample measured by XRD contains magnesium oxide, peaks are mainly observed at the measurement angles indicated by the one dot chain lines in the spectral data obtained by the measurement.

As shown in FIG. 6, the peaks indicating the presence of zinc oxide were observed in both the spectral data D5 and the spectral data D6. Thus, it was confirmed that a material having a crystal structure of zinc oxide was contained in the first solution and the second solution synthesized by the above-described method. On the other hand, although a peak P indicating the presence of magnesium oxide was observed at a measurement angle of about 42 degrees in the spectral data D6, a peak at the same measurement angle was not observed in the spectral data D5. Thus, it was confirmed that the material having the crystal structure of magnesium oxide was contained in the second solution synthesized by the above-described method, but was not contained in the first solution.

Furthermore, elements contained in the first solution and the second solution may be identified by elemental analysis using an inductively coupled plasma atomic emission spectrometer (ICP-AES), an X-ray photo-electron spectroscopy (XPS), or the like.

For example, it may be confirmed that Mg is contained in the first solution by actually performing elemental analysis by ICP-AES or XPS on the first solution synthesized by the method described above. In this case, it can be seen that although magnesium oxide is not contained in the first solution, a material having the crystal structure of zinc oxide and further containing Mg atoms is synthesized. In other words, it can be seen that the nanoparticles 30s each containing magnesium zinc oxide as the first material are synthesized in the first solution. Thus, it can be seen that the second solution synthesized from the first solution also contains the nanoparticles 30s each containing magnesium zinc oxide as the first material.

As described above, it was confirmed that the nanoparticles 30s each containing magnesium zinc oxide as the first material were contained in the first solution. In addition, it was confirmed that the nanoparticles 30s each containing magnesium zinc oxide as the first material and the second material portion 31 containing magnesium oxide as the second material were contained in the second solution.

### Manufacturing Method for Light-Emitting Element: Formation of Electron Transport Layer and Cathode

In the manufacturing method for the light-emitting element 1, after step S4 and step S8 are completed, the second solution is applied onto the light-emitting layer 13 by a spin coating method or the like (step S9). Next, the electron transport layer 14 containing the nanoparticle structures 20s is formed by drying the applied second solution (step S10). The thickness of the electron transport layer 14 thus formed may be 40 nm.

In steps S9 and S10, the quantum dots 40s of the light-emitting layer 13 that have already been formed are protected by the inorganic matrix material 41. Thus, the light-emitting layer 13 can protect the quantum dots 40s from deterioration in a forming process of the second solution by the inorganic matrix material 41. Thus, the manufacturing method for the light-emitting element 1 according to the present embodiment reduces the deterioration of the light-emitting layer 13 and improves the reliability of the light-emitting element 1.

Next, similarly to the anode 10, the cathode 15 is formed by depositing a conductive material on the electron transport layer 14 by sputtering, a vacuum vapor deposition technique, or the like (step S11). Specifically, the cathode 15 may be formed by, for example, depositing a thin film of Ag having a film thickness of 50 nm on the electron transport layer 14 by a vacuum vapor deposition technique.

### Summary of First Embodiment

The light-emitting element 1 according to the present embodiment includes, as the intervening layer, the electron transport layer 14 containing the nanoparticle structures 20. The nanoparticle structure 20 includes the nanoparticle 30 made of the first material containing metal oxide, and the second material portion 31 formed on at least part of the surface 30s of the nanoparticle 30 and made of the inorganic second material having the electron transport ability lower than that of the first material.

Thus, for the above-described reason, the light-emitting element 1 can improve the carrier balance of the light-emitting layer 13 while reducing the drive voltage by the electron transport layer 14. In addition, the light-emitting element 1 reduces the thickness of the entire light-emitting element 1 and reduces the drive voltage as compared with the case where the electron transport layer has a layered structure of a layer made of the first material and a layer made of the second material. Furthermore, the light-emitting element 1 makes the conduction from the cathode 15 to the light-emitting layer 13 via the electron transport layer 14 more reliable and reduces the drive voltage as compared with the case where the electron transport layer contains the nanoparticle made of the first material and the nanoparticle made of the second material.

Furthermore, the light-emitting element 1 includes the light-emitting layer 13 containing the plurality of quantum dots 40s and the inorganic matrix material 41 that fills the spaces between the quantum dots 40s. Thus, for the reason described above, the light-emitting element 1 can further reduce the excessive electrons in the light-emitting layer 13 and improve the carrier balance. Thus, since the light-emitting element 1 includes the light-emitting layer 13 and the electron transport layer 14, the light-emitting element 1 can suppress the excessive electrons in the light-emitting layer 13 while reducing the drive voltage and achieve both reduction of the drive voltage and improvement in the luminous efficiency and reliability.

The electron transport layer 14 according to the present embodiment is formed by applying the second solution. In the present embodiment, the second solution containing the nanoparticle structures 20s in which the second material portion 31 is formed on the surface of at least part of the nanoparticle 30 is synthesized by adding the second material to the first solution containing the nanoparticles 30s and performing the ultrasonic treatment. In other words, in the present embodiment, the nanoparticle structure 20 is synthesized in a state where the first material and the second material are always in the solvent. Thus, in the present embodiment, the nanoparticle structures 20s can be formed while ensuring the dispersibility of the nanoparticles 30s containing the first material and the second material in the second solution.

For example, due to a difference in dispersibility between the first material and the second material, it may be difficult to form the electron transport layer containing both materials from a solution obtained by mixing the nanoparticle made of the first material and the nanoparticle made of the second material. According to the method for forming the electron transport layer 14 of the present embodiment, since the nanoparticle structure 20 is synthesized while ensuring the dispersibility of each material in the second solution, the nanoparticle structure 20 can be easily synthesized even when there is a difference in dispersibility between the first material and the second material.

Thus, according to the manufacturing method for the light-emitting element 1 of the present embodiment, since the degree of freedom in designing the first material and the second material is further increased, it is easier to design the electron transport layer 14 that can further improve the carrier balance in the light-emitting layer 13. Thus, the manufacturing method for the light-emitting element 1 according to the present embodiment can provide the light-emitting element 1 that can improve the carrier balance in the light-emitting layer 13.

Furthermore, according to the manufacturing method for the light-emitting element 1 according to the present embodiment, the electron transport layer 14 can be formed without going through a process such as sputtering that may cause deactivation of the light-emitting material including the quantum dots 40s of the light-emitting layer 13. In addition, according to the above-described method, the nanoparticle structure 20 can be synthesized by heating the second solution rapidly and for a short period of time by the ultrasonic treatment on the second solution, and damage to each material of the second solution due to heating can be reduced. In addition, in a forming process of the electron transport layer 14, the quantum dots 40s are protected by the inorganic matrix material 41. Thus, the manufacturing method for the light-emitting element 1 according to the present embodiment can reduce damage to the light-emitting layer 13 and the electron transport layer 14 and provide the light-emitting element 1 with higher reliability.

In the present embodiment, as illustrated in FIG. 1, an example in which the second material portion 31 is formed on the entire surface 30s of the nanoparticle 30 in the nanoparticle structure 20 has been described. However, the present embodiment is not limited to this. For example, the second material portion 31 may be formed on at least part of the surface 30s of the nanoparticle 30.

For example, in the present embodiment, the second material portion 31 may cover 10% or more of the outer periphery of the nanoparticle 30 in the cross section of the nanoparticle 30. For example, it may be confirmed by elemental analysis of the thin piece obtained by dividing the electron transport layer 14 in the layering direction of the light-emitting element 1 that the second material portion 31 covers 10% or more of the outer periphery of the nanoparticle 30 at any location. In this case, uniformity of the particle diameter of the nanoparticle structure 20 is improved, film thickness unevenness of the electron transport layer 14 is reduced, and the stability of a path through which electrons are transported in the electron transport layer 14 is improved. In addition, in the above case, since inhibition of the electron transport by the second material portion 31 occurs more reliably, the excessive electrons in the light-emitting layer 13 is further reduced. Thus, the electron transport layer 14 further achieve reduction of the excessive electrons in the light-emitting layer 13 and reduction of the drive voltage of the light-emitting element 1. The second material portion 31 more desirably covers at least ⅙ of the outer periphery of the nanoparticle 30 in the cross section of the nanoparticle 30. A “ratio of covering the outer periphery” in the disclosure means a ratio on the outer periphery in one cross section of the nanoparticle 30, and does not mean a ratio in the three dimensional surface area of the nanoparticle 30.

Depending on conditions of the manufacturing method for the light-emitting element 1 described above, the nanoparticles 30s with low uniformity may be obtained in step S5. In this case, prior to step S6, a shell layer made of the first material same as the first material of the nanoparticle 30 may be formed on the surface of the nanoparticle 30. Thus, the uniformity of the nanoparticles 30s is improved, and thus the uniformity of the nanoparticle structures 20s is improved.

The quantum dot 40 according to the present embodiment may not contain cadmium as described above. In general, high characteristics can be obtained by using a light-emitting material containing cadmium. However, it is possible to reduce the load on the environment by using the light-emitting material not containing cadmium.

As the quantum dot 40 not containing cadmium, for example, a quantum dot having a core/shell structure of InP/ZnS, InP/ZnSe, or the like can be employed. In this case, a mixed crystal layer obtained by indium of InP of the core of the quantum dot 40 and zinc of ZnS or ZnSe of the quantum dot 40 being exchanged with each other may be formed between the core and the shell of the quantum dot 40.

In the mixed crystal layer, the core and the shell form a pn junction. Thus, in the injection of carriers from the shell into the core of the quantum dot 40, the mixed crystal layer does not serve as a barrier to the injection of electrons but can serve as a barrier to the injection of holes. Thus, in the light-emitting element 1 including the light-emitting layer 13 containing the above-described quantum dots 40, the excessive electrons in the light-emitting layer 13 may become worse.

The light-emitting element 1 according to the present embodiment can employ a configuration including the light-emitting layer 13 that can reduce the excessive electrons while containing the quantum dots 40s each not containing cadmium as the light-emitting material, and the electron transport layer 14 that can reduce the excessive electrons in the light-emitting layer 13. With this configuration, the light-emitting element 1 can reduce the environmental load, and facilitate handling such as disposal or recycling of a product including the light-emitting element 1 while further reducing the excessive electrons in the light-emitting layer 13 and reducing the drive voltage.

As described above, the light-emitting element 1 according to the present embodiment may include the hole injection layer 11 containing the inorganic material. In general, when a light-emitting element includes a hole injection layer containing an inorganic material, the reliability is improved as compared with the case where the light-emitting element includes a hole injection layer containing an organic material. However, since the efficiency of the hole transport in the hole injection layer is reduced, the excessive electrons in the light-emitting layer may become worse.

However, the light-emitting element 1 according to the present embodiment includes the light-emitting layer 13 and the electron transport layer 14 that can reduce the excessive electrons in the light-emitting layer 13. Thus, according to the present embodiment, even when the light-emitting element 1 includes the hole injection layer 11 containing the inorganic material as described above, by including such an electron transport layer 14, it is possible to further enhance the reliability of the light-emitting element 1 while reducing the excessive electrons in the light-emitting layer 13.

Furthermore, as described above, the light-emitting element 1 according to the present embodiment may include the hole transport layer 12 containing the organic material. In this case, since the light-emitting element 1 improves the efficiency of the hole transport in the hole transport layer 12 as compared with the case where the hole transport layer 12 containing the inorganic material is included, the light-emitting element 1 can further reduce the excessive electrons in the light-emitting layer 13. For example, the light-emitting element 1 may include the hole injection layer 11 containing the inorganic material and the hole transport layer 12 containing the organic material. In this case, it is possible to further reduce the excessive electrons in the light-emitting layer 13 by the hole transport layer 12 while ensuring reliability by the hole injection layer 11.

### Supplement

In the present embodiment, for example, the inorganic matrix material 41 and the second material portion 31 may contain the same metal sulfide, and in particular, may contain a zinc sulfide-based material. For example, the inorganic matrix material 41 and the second material portion 31 may contain ZnS, ZnMgS, or the like.

The inorganic matrix material 41 and the second material portion 31 may contain the same metal oxide, and in particular, may contain silicon oxide. For example, the inorganic matrix material 41 and the second material portion 31 may contain SiO2 or the like.

The inorganic matrix material 41 and the electron transport layer 14 each containing the metal sulfide or the metal oxide can efficiently reduce the efficiency of the electron injection into the light-emitting layer 13 and efficiently improve the luminous efficiency of the light-emitting layer 13. In addition, the metal sulfide and the metal oxide contain sulfur and oxygen, respectively, which are elements whose abundance in the earth's crust is relatively high as compared with other elements in general. Thus, the inorganic matrix material 41 and the electron transport layer 14 each containing the metal sulfide or the metal oxide can be produced from a material having a relatively large production amount in the earth. In particular, zinc contained in the zinc sulfide-based material and silicon contained in silicon oxide are elements whose abundance in the earth's crust is relatively high as compared with other elements in general. As described above, the metal sulfide and the metal oxide described above are useful as the materials of the inorganic matrix material 41 and the electron transport layer 14 from the viewpoint of reducing the excessive electrons in the light-emitting layer 13, improving the luminous efficiency of the light-emitting element 1, and reducing the cost of the light-emitting element 1.

The electron transport layer 14 of the light-emitting element 1 may contain the nanoparticles 30s each containing magnesium zinc oxide as the first material and the second material portion 31 containing the metal oxide as the second material. Since magnesium zinc oxide is soluble in alkali, it is possible to improve the process tolerability by forming the second material portion 31 containing the metal oxide other than magnesium zinc oxide and having tolerability to alkali.

Examples of the metal oxide having tolerability to alkali used as the second material include aluminum oxide (for example, Al₂O₃). As described above, a composition represented by a chemical formula in the disclosure is desirably stoichiometric. However, other than stoichiometry is not excluded.

In addition, the inorganic matrix material 41 and the electron transport layer 14 of the light-emitting element 1 may contain the second material portion 31 containing magnesium oxide having high optical transparency as the second material. Here, when the light-emitting element 1 is the top-emitting type in which light is extracted from the quantum dots 40s to the cathode 15 side, the electron transport layer 14 reduces absorption of light from the quantum dots 40s by the second material portion 31 of the electron transport layer 14. In addition, the inorganic matrix material 41 reduces absorption of light from the quantum dots 40s by the inorganic matrix material 41 regardless of an extraction direction of light from the quantum dots 40s by the light-emitting element 1. Thus, according to the configuration described above, the light-emitting element 1 can further increase light extraction efficiency.

### Second Embodiment

Another embodiment of the disclosure will be described below. Below, for convenience of description, members having the same function as the members described in the above-described embodiments will be denoted by the same reference numerals and signs, and descriptions thereof will not be repeated.

### Modified Example of Nanoparticle Structure

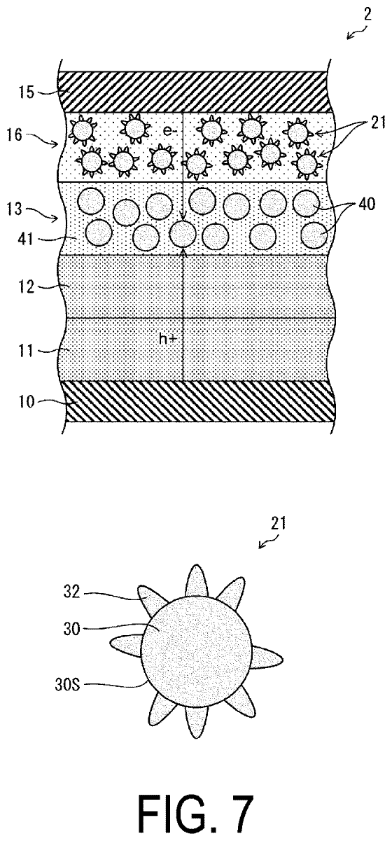

FIG. 7 is views illustrating a schematic cross-sectional view of a light-emitting element 2 according to the present embodiment and a schematic cross-sectional view of a nanoparticle structure 21 to be described later, which are arranged side by side. Note that the schematic cross-sectional view of the light-emitting element 2 in FIG. 7 illustrates a cross section corresponding to the schematic cross-sectional view of the light-emitting element 1 in FIG. 1. Similarly to the schematic cross-sectional view of the nanoparticle structure 20 illustrated in FIG. 1, the schematic cross-sectional view of the nanoparticle structure 21 illustrated in FIG. 7 simply illustrates a cross section of the nanoparticle structure 21 passing through the center of the nanoparticle 30.

The light-emitting element 2 according to the present embodiment is different in a configuration from the light-emitting element 1 according to the first embodiment only in that the light-emitting element 2 includes an electron transport layer 16 instead of the electron transport layer 14. The electron transport layer 16 is different in a configuration from the electron transport layer 14 only in that the electron transport layer 16 contains the nanoparticle structure 21 instead of the nanoparticle structure 20. In other words, similarly to the electron transport layer 14, the electron transport layer 16 transports electrons e injected from the cathode 15 to the light-emitting layer 13.

The nanoparticle structure 21 includes second material portions 32s each formed in island shapes on the surface 30s of the nanoparticle 30. The second material portion 32 is made of the same material as the second material portion 31 according to the first embodiment, in other words, the second material.

Thus, the electron transport layer 16 is an intervening layer containing the nanoparticles 30s each made of the first material containing the metal oxide and the second material portion 32s each made of the inorganic second material located in island shapes in part of the surface 30s of the surface of the nanoparticle 30 and has an electron transport ability lower than that of the first material. Furthermore, the light-emitting element 2 includes the light-emitting layer 13 containing the plurality of quantum dots 40s and the inorganic matrix material 41 that fills the spaces between the quantum dots 40s. Thus, for the same reason as the reason described in the first embodiment, the light-emitting element 2 can improve the carrier balance of the light-emitting layer 13 while reducing the drive voltage by the light-emitting layer 13 and the electron transport layer 16.

The analysis of the structure of the electron transport layer 16 may be performed by the same method as the analysis of the structure of the electron transport layer 14 described above. Specifically, the elemental analysis of the electron transport layer 16 may be performed by dividing the electron transport layer 16 in the layering direction of the light-emitting element 2 into thin pieces, observing the thin piece with TEM or the like, and performing the elemental analysis using EDX, EELS, or the like. Also in the present embodiment, EELS is used when measurement cannot be performed by EDX.

For example, in the above-described thin piece, it is assumed to be confirmed that at least part of the member containing the second material is formed in part and a plurality of locations of the outer periphery of the member containing the first material. In this case, it may be determined that the electron transport layer 16 contains the nanoparticle structure 21 including the nanoparticle 30 made of the first material and the second material portions 32s located in island shapes on the surface 30s of the nanoparticle 30. Thus, the second material portions 32s being located in island shapes on the surface 30s of the nanoparticle 30 is equivalent to the second material portions 32s being located in island shapes on the outer periphery of the nanoparticle 30 in the cross section of the nanoparticle 30. As described above, the fact that the electron transport layer 16 contains the structure of the nanoparticle structure 21 can be confirmed by, for example, the elemental analysis of the above-described thin piece. Also in this case, the “outer periphery of the member” refers to the region in the range of 2 nm from the end portion of the member. That is, in order to confirm the nanoparticle structure 21, it is conceivable to confirm that at least part of the member containing the second material is formed in part and the plurality of locations of the region in the range of 2 nm from at least part of the end portion of the member containing the first material. Thus, the nanoparticle structure 21 including the nanoparticle 30 made of the first material and the second material portions 32s located in island shapes on the surface 30s of the nanoparticle 30 can be confirmed.

The thickness of the second material portions 32s, in other words, the thickness from the surface 30s of the nanoparticle 30 to the outermost periphery of the nanoparticle structure 21 may be 0.4 nm or more and 2.0 nm or less, or 0.4 nm or more and 1.0 nm or less. When the thickness of the second material portions 32s is 0.4 nm or more, the second material portions 32s can be more reliably formed on the surface 30s of the nanoparticle 30 by a method to be described later. In addition, when the thicknesses of the second material portions 32s is 2.0 nm or less, carriers can move by tunnel conduction, and when the thickness is 1.0 nm or less, an effect of reducing the drive voltage (power consumption) of the light-emitting element 2 can be more efficiently obtained. The thickness of the second material portions 32s may be measured by the above-described elemental analysis using EDX, EELS, or the like.

Similarly to the second material portion 31, the second material portions 32s may cover 10% or more of the outer periphery of the nanoparticle 30 in the cross section of the nanoparticle 30. For example, it may be confirmed by the elemental analysis of the thin piece obtained by dividing the electron transport layer 14 in the layering direction of the light-emitting element 1 that the second material portion 32 covers 10% or more of the outer periphery of the nanoparticle 30 at any location.

In addition, the nanoparticle structure 21 may have a structure in which the second material portions 32s covers 90% or less of the outer periphery of nanoparticle 30 in the cross section of nanoparticle 30. The structure may be confirmed by, for example, confirming that the second material portions 32s cover 90% or less of the outer periphery of the nanoparticle 30 at any location by the elemental analysis of the above-described thin piece.

According to the present embodiment, as described above, the second material portions 32s are located in island shapes on the outer periphery of the nanoparticle 30 in the cross section of the nanoparticle 30, so that the effective particle diameter of the nanoparticle structure 21 can be small as compared with the case where the entire outer periphery of the nanoparticle 30 is covered with the second material portions 32s. As described above, the effective particle diameter of the nanoparticle structure 21 can also be small by adopting a structure in which 90% or less of the outer periphery of the nanoparticle 30 is covered with the second material portions 32s in the cross section of the nanoparticle 30. Thus, according to the present embodiment, it is possible to reduce an increase in the particle diameter size of the nanoparticle structure in the electron transport layer 16. Thus, in the present embodiment, the applied voltage of the light-emitting element 2 can be further reduced by increasing the concentration of the nanoparticle structures 21s in the electron transport layer 16 and improving the efficiency of the electron transport.

The light-emitting element 2 can control a degree of inhibition of the electron transport by the second material portions 32s by appropriately changing conditions in the above-described manufacturing method to change the ratio of the second material portions 32s covering the outer periphery of the nanoparticle 30 in the cross section of the nanoparticle 30. Thus, the light-emitting element 2 can more easily achieve both the reduction in the excessive electrons in the light-emitting layer 13 and reduction in the applied voltage.

The light-emitting element 2 according to the present embodiment may be manufactured by changing part of the manufacturing method for the light-emitting element 1 according to the first embodiment. For example, in the manufacturing method for the light-emitting element 2, the light-emitting element 2 may be manufactured by appropriately changing the concentration or the type of the second material added to the first solution in step S6, the conditions of the ultrasonic treatment in step S7, or the like in the manufacturing method for the light-emitting element 1.

Thus, in the manufacturing method for the light-emitting element 2 according to the present embodiment, as described in the first embodiment, the nanoparticle structure 21 is synthesized while ensuring the dispersibility of each material in the second solution. Thus, also in the present embodiment, even when there is a difference in dispersibility between the first material and the second material, it is possible to easily synthesize the nanoparticle structure 21. Thus, for the same reason as the reason described in the first embodiment, the manufacturing method for the light-emitting element 2 according to the present embodiment can provide the light-emitting element 2 that can improve the carrier balance in the light-emitting layer 13.

### Third Embodiment

### Light-Emitting Element Not Including Hole Injection Layer

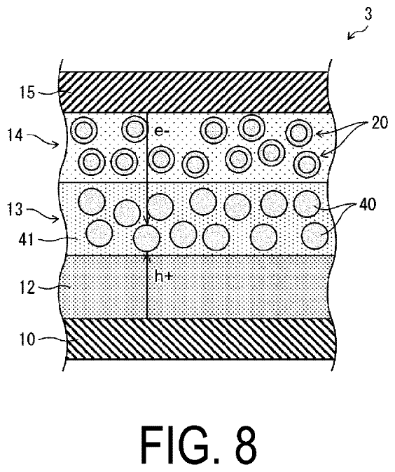

FIG. 8 is a schematic cross-sectional view of a light-emitting element 3 according to the present embodiment. Note that the schematic cross-sectional view of the light-emitting element 3 in FIG. 8 illustrates a cross section corresponding to the schematic cross-sectional view of the light-emitting element 1 in FIG. 1.

The light-emitting element 3 according to the present embodiment is different in a configuration from the light-emitting element 1 according to the above-described first embodiment only in that the light-emitting element 3 does not include the hole injection layer 11. In other words, in the present embodiment, holes from the anode 10 are injected into the hole transport layer 12 and transported to the light-emitting layer 13 via the hole transport layer 12.

The light-emitting element 3 according to the present embodiment includes the electron transport layer 14 containing the nanoparticle structures 20, as in the light-emitting element 1. The light-emitting element 3 includes the light-emitting layer 13 containing the plurality of quantum dots 40s and the inorganic matrix material 41 that fills the spaces between the quantum dots 40s. Thus, for the same reason as the reason described above, the light-emitting element 3 according to the present embodiment can also improve the carrier balance of the light-emitting layer 13 while reducing the drive voltage by the light-emitting layer 13 and the electron transport layer 14. Furthermore, the light-emitting element 3 according to the present embodiment does not include the hole injection layer 11, unlike the light-emitting element 1 or the light-emitting element 2. Thus, the light-emitting element 3 further reduces the thickness between the electrodes, and thus the drive voltage can be further reduced.

In the present embodiment, the hole transport layer 12 may contain the above-described inorganic material having hole transport properties. As described above, the light-emitting element 3 according to the present embodiment can employ a configuration including the hole transport layer 12 containing the inorganic material, and the light-emitting layer 13 and the electron transport layer 14 that can reduce the excessive electrons in the light-emitting layer 13. With this configuration, for the same reason as the reason described above, the light-emitting element 3 can further enhance the reliability of the light-emitting element 1 while further reducing the excessive electrons in the light-emitting layer 13.

The light-emitting element 3 according to the present embodiment may be manufactured by a method in which only step S2 is omitted in the above-described manufacturing method for the light-emitting element 1. In other words, in the present embodiment, the hole transport layer 12 may be formed on the anode 10. Thus, for the same reason as the reason described in the above-described embodiments, the manufacturing method for the light-emitting element 3 according to the present embodiment can provide the light-emitting element 2 that can improve the carrier balance in the light-emitting layer 13.

### Fourth Embodiment

### Display Device

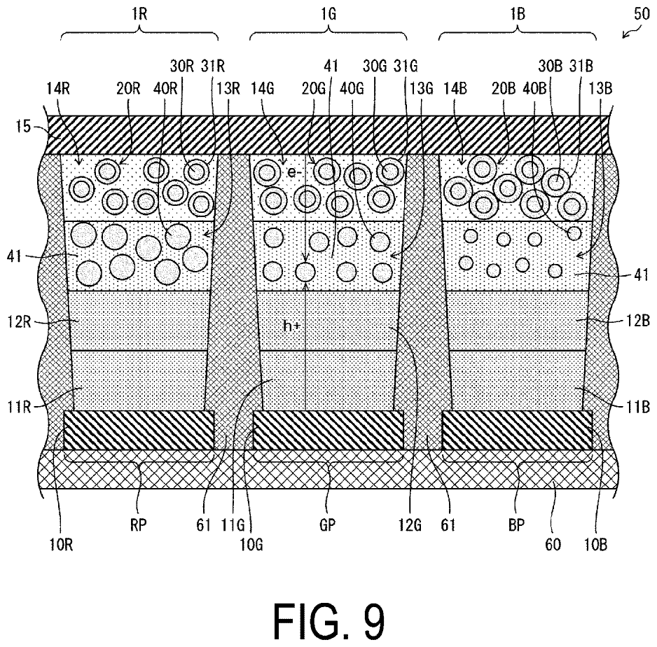

In another embodiment of the disclosure, a display device including the above-described light-emitting element 1 will be described. FIG. 9 is a schematic cross-sectional view of a display device 50 according to the present embodiment.

The display device 50 according to the present embodiment is a display device in which each of a plurality of subpixels includes a respective one of a plurality of light-emitting elements and performs display by individually driving each light-emitting element. The display device 50 includes, as will be described later, a plurality of red light-emitting elements 1Rs that emit red light, a plurality of green light-emitting elements 1Gs that emit green light, and a plurality of blue light-emitting elements 1Bs that emit blue light. FIG. 9 illustrates a cross section of the display device 50 passing through each layer of respective one red light-emitting element 1R, one green light-emitting element 1G, and one blue light-emitting element 1B in the layering direction of the light-emitting elements of the display device 50.

The red light-emitting element 1R includes an anode 10R, a hole injection layer 11R, a hole transport layer 12R, a red light-emitting layer 13R, an electron transport layer 14R, and a cathode 15 in this order from below. The green light-emitting element 1G includes an anode 10G, a hole injection layer 11G, a hole transport layer 12G, a green light-emitting layer 13G, an electron transport layer 14G, and a cathode 15 in this order from below. The blue light-emitting element 1B includes an anode 10B, a hole injection layer 11B, a hole transport layer 12B, a blue light-emitting layer 13B, an electron transport layer 14B, and a cathode 15 in this order from below.

At least one of the red light-emitting element 1R, the green light-emitting element 1G, and the blue light-emitting element 1B may have the same configuration as that of the light-emitting element 1 according to the first embodiment except for the luminescent color of each light-emitting layer and the configuration of each electron transport layer. The red light-emitting element 1R, the green light-emitting element 1G, and the blue light-emitting element 1B may include the cathode 15 in common. In FIG. 9, a case will be described as an example in which the red light-emitting element 1R, the green light-emitting element 1G, and the blue light-emitting element 1B have the same configuration except for the luminescent color of each light-emitting layer and the configuration of each electron transport layer.

Specifically, the red light-emitting layer 1R of the red light-emitting element 13R contains red quantum dots 40Rs that emit red light. The green light-emitting layer 1G of the green light-emitting element 13G contains green quantum dots 40Gs that emit green light. The blue light-emitting layer 1B of the blue light-emitting element 13B contains blue quantum dots 40Bs that emit blue light. The red quantum dot 40R, the green quantum dot 40G, and the blue quantum dot 40B may have the same configuration as the quantum dot 40 except for the luminescent color. The luminescent color of each quantum dot may be changed by changing the particle diameter of the quantum dot.

The red light refers to light having an emission center wavelength in a wavelength band greater than 600 nm and 780 nm or less. The green light refers to, for example, light having an emission center wavelength in a wavelength band greater than 500 nm and 600 nm or less. Furthermore, the blue light refers to, for example, light having an emission center wavelength in a wavelength band 400 nm or greater and 500 nm or less.

In each of the red light-emitting element 1R, the green light-emitting element 1G, and the blue light-emitting element 1B illustrated in FIG. 9, the electron transport layer contains the nanoparticle structures each having the structure described in the first embodiment. The electron transport layer 1R of the red light-emitting element 14R contains nanoparticle structures 20R. The electron transport layer 1G of the green light-emitting element 14G contains nanoparticle structures 20G. The electron transport layer 1B of the blue light-emitting element 14B contains nanoparticle structures 20B. The nanoparticle structure 20R, the nanoparticle structure 20G, and the nanoparticle structure 20B are different from each other in a ratio of covering the outer periphery of the nanoparticle 30 by the second material portion 31 or in the thickness of the second material portion 31 in the cross section of the nanoparticle 30. Except for the above, the nanoparticle structure 20R, the nanoparticle structure 20G, and the nanoparticle structure 20B may have the same configuration as that of the nanoparticle structure 20 according to the first embodiment.

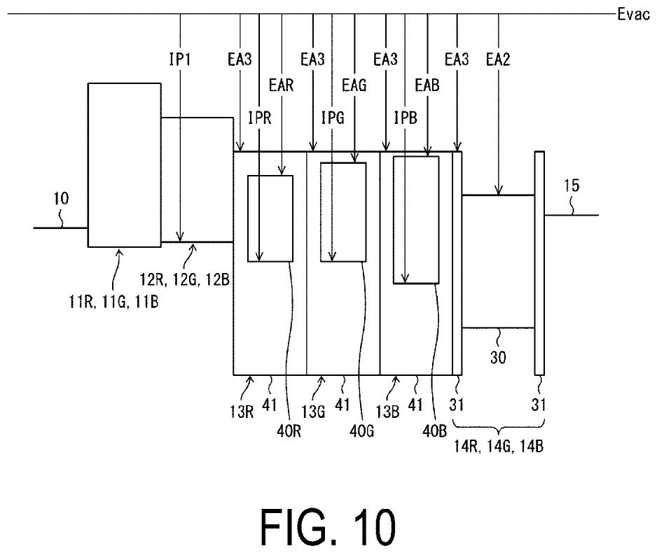

With respect to any two light-emitting elements of the red light-emitting element 1R, the green light-emitting element 1G, and the blue light-emitting element 1B, the light-emitting element having the shorter light emission wavelength is a short-wavelength element, and the light-emitting element having the longer light emission wavelength is a long-wavelength element. In this case, in the present embodiment, the ratio of the cross-sectional area of the second material to the cross-sectional area of the first material in the electron transport layer of each light-emitting element is smaller in the long-wavelength element than in the short-wavelength element. By doing so, as will be described in detail in the description of FIG. 10 below, the carrier balance can be adjusted, and the drive voltage (power consumption) of the light-emitting element can be further reduced.

For example, the ratio of the cross-sectional area of the second material to the cross-sectional area of the first material in the electron transport layer 14R is smaller than the ratio of the cross-sectional area of the second material to the cross-sectional area of the first material in the electron transport layer 14G. Alternatively, the ratio of the cross-sectional area of the second material to the cross-sectional area of the first material in the electron transport layer 14G is smaller than the ratio of the cross-sectional area of the second material to the cross-sectional area of the first material in the electron transport layer 14B. Alternatively, the ratio of the cross-sectional area of the second material to the cross-sectional area of the first material in the electron transport layer 14R is smaller than the ratio of the cross-sectional area of the second material to the cross-sectional area of the first material in the electron transport layer 14B.

In the present embodiment, the ratio of the cross-sectional area of the second material to the cross-sectional area of the first material in the electron transport layer of each light-emitting element may be changed by changing the ratio of the second material portion 31 covering the outer periphery of the nanoparticle 30 in the cross section of the nanoparticle 30 in each electron transport layer. In addition, the ratio of the cross-sectional area of the second material to the cross-sectional area of the first material in the electron transport layer of each light-emitting element may be changed by changing the thickness of the second material portion 31 in each electron transport layer. For example, in the long-wavelength element than in the short-wavelength element, the ratio of the surface 30s of the nanoparticle 30 on which the second material portion 31 is formed may be reduced or the thickness of the second material portion 31 may be reduced.

The display device 50 includes a substrate 60. A plurality of red subpixels RP, a plurality of green subpixels GP, and a plurality of blue subpixels BP are formed on the substrate 60. A plurality of light-emitting elements are formed on the substrate 60, and in particular, the red light-emitting elements 1R are formed in the respective red subpixels RP, the green light-emitting elements 1G are formed in the respective green subpixels GP, and the blue light-emitting elements 1B are formed in the respective blue subpixels BP.

Furthermore, the red light-emitting layer 13R, the green light-emitting layer 13G, and the blue light-emitting layer 13B each contain the inorganic matrix material 41 that fills spaces between the quantum dots. The inorganic matrix material 41 may have the same composition or may be different from each other in the red light-emitting layer 13R, the green light-emitting layer 13G, and the blue light-emitting layer 13B. In particular, the inorganic matrix material 41 may have the same composition as the second material contained in the second material portion 31 of each electron transport layer.

The red light-emitting element 1R, the green light-emitting element 1G, and the blue light-emitting element 1B are disposed such that the respective anodes are formed on the substrate 60 side. Thus, on the substrate 60, the anode of each light-emitting element is formed in island shapes for a respective one of the subpixels, and the cathode 15 is formed in common to the plurality of subpixels. The display device 50 causes each light-emitting element to individually emit light by individually driving each cathode on the substrate 60 by a TFT (not illustrated) or the like formed for each subpixel on the substrate 60 while setting the cathode 15 to a predetermined potential. Thus, the display device 50 enables full color display.

The display device 50 includes banks 61s. The bank 61 is formed on the substrate 60, and divides the anode to the electron transport layer of each light-emitting element included in the display device 50 into subpixels. For example, the bank 61 may be formed at a location overlapping an end portion of the anode in order to reduce electrical field concentration in the vicinity of the end portion of the anode of each light-emitting element. The bank 61 may be made of a resin material such as polyimide or may contain a photosensitive resin.

The display device 50 according to the present embodiment may be manufactured by preparing the substrate 60 and then forming each light-emitting element on the substrate 60 by the same method as the manufacturing method for the light-emitting element 1 according to the first embodiment.

More specifically, for example, first, a thin film of the anode is formed on the substrate 60 and then patterned for each subpixel. Next, the bank 61 is formed on the substrate 60 and on each anode by photolithography or the like using a photosensitive resin or the like. Next, a hole injection layer, a hole transport layer, a light-emitting layer, and an electron transport layer of each light-emitting element are formed in each subpixel by separately patterning by an ink-jet method or the like, patterning by photolithography using the photosensitive resist, or the like. Next, the cathode 15 common to the plurality of subpixels is formed by sputtering or the like. As described above, the display device 50 may be manufactured.

Here, when each light-emitting layer of the display device 50 is formed by patterning, there is a possibility that a light-emitting layer that has already been formed is exposed to a process such as exposure to a developer that may cause deterioration of the quantum dots of the light-emitting layer. However, in the display device 50, since the quantum dots of each light-emitting layer are protected by the inorganic matrix material 41, the display device 50 can reduce deterioration of each light-emitting layer due to the above-described patterning.

The luminescent color of each light-emitting layer may be changed by changing the particle diameter of the quantum dot contained in the layer to be deposited in the forming process of each light-emitting layer. In addition, in each electron transport layer, the ratio of the surface 30s of the nanoparticle 30 on which the second material portion 31 is formed or the thickness of the second material portion 31 may be changed by changing the concentration or the like of the second material added to the first solution in the forming process of each electron transport layer.

FIG. 10 is a schematic energy band diagram of each layer of the display device 50 illustrated in FIG. 9. In FIG. 10, the respective Fermi levels of the anode 10 and the cathode 15 are illustrated. FIG. 10 illustrates the band gaps of each hole injection layer, each hole transport layer, each light-emitting layer, and each electron transport layer in the display device 50.

In the present embodiment, the red light-emitting layer 13R, the green light-emitting layer 13G, and the blue light-emitting layer 13B do not overlap each other in a plan view of the display device 50. However, in order to facilitate comparison of the band gaps in the respective light-emitting layers, in the energy band diagram illustrated in FIG. 10, the band gaps of the respective light-emitting layers are illustrated side by side in the same energy band diagram.

As described above, the red light-emitting element 1R, the green light-emitting element 1G, and the blue light-emitting element 1B illustrated in FIG. 9 have the same configuration each other except for the luminescent color of each light-emitting layer and the configuration of each electron transport layer. Thus, in FIG. 10, the same material is used for the hole injection layers 11R, 11G, and 11B. In FIG. 10, the same material is used for the hole transport layers 12R, 12G, and 12B. Thus, the band gap of the hole injection layer 11R, the band gap of the hole injection layer 11G, and the band gap of the hole injection layer 11B are the same as each other. Similarly, the band gap of the hole transport layer 12R, the band gap of the hole transport layer 12G, and the band gap of the hole transport layer 12B are the same as each other.

In the present embodiment, as described above, the ratio of the cross-sectional area of the second material to the cross-sectional area of the first material in the electron transport layer of each light-emitting element is changed for each emission wavelength of a corresponding light-emitting element. However, for convenience of description, FIG. 10 illustrates the band gaps when the electron transport layer 14R, the electron transport layer 14G, and the electron transport layer 14B have the same configuration and are made of the same material as each other.

In FIG. 10, the band gap of the red quantum dot 40R is illustrated for the red light-emitting layer 13R, the band gap of the green quantum dot 40G is illustrated for the green light-emitting layer 13G, and the band gap of the blue quantum dot 40B is illustrated for the blue light-emitting layer 13B. FIG. 10 illustrates the band gaps of the nanoparticle 30 made of the first material and the second material portion 31 made of the second material for the electron transport layer 14. Note that the energy band diagram of FIG. 10 also illustrates the energy level of each layer with reference to the vacuum level Evac.

As described above, the luminescent color of each quantum dot can be changed by changing the particle diameter of the quantum dot. The particle diameter of the quantum dot becomes smaller as the emission wavelength becomes shorter. Thus, as illustrated in FIG. 9, the particle diameter of the green quantum dot 40G is smaller than the particle diameter of the red quantum dot 40R, and the particle diameter of the blue quantum dot 40B is smaller than the particle diameter of the green quantum dot 40G. Thus, as the emission wavelength becomes shorter, it becomes more difficult for holes to be injected into the light-emitting layer, resulting in a state of further excess of electrons.

An ionization potential of the hole transport layer 12 is IP1, an ionization potential of the red light-emitting layer 13R is IPR, an ionization potential of the green light-emitting layer 13G is IPG, and an ionization potential of the blue light-emitting layer 13B is IPB. As illustrated in FIG. 10, in the embodiment, the ionization potential IP1 of the hole transport layer 12 is less than the ionization potential IPR of the red light-emitting layer 13R, the ionization potential IPG of the green light-emitting layer 13G, and the ionization potential IPB of the blue light-emitting layer 13B.

The ionization potential IP1 of the hole transport layer 12 is represented by an absolute value of an energy difference between the vacuum level Evac and an upper end of the valance band (VBM) of the hole transport layer 12. The ionization potential IPR of the red light-emitting layer 13R is represented by an absolute value of an energy difference between the vacuum level Evac and the VBM of the red light-emitting layer 13R. The ionization potential IPG of the green light-emitting layer 13G is represented by an absolute value of an energy difference between the vacuum level Evac and the VBM of the green light-emitting layer 13G. The ionization potential IPB of the blue light-emitting layer 13B is represented by an absolute value of an energy difference between the vacuum level Evac and the VBM of the blue light-emitting layer 13B.

In general, in the charge injection type light-emitting element, the height of a barrier when holes are injected from a first layer into a second layer adjacent to the first layer is represented by an energy difference between the VBM of the second layer and the VBM of the first layer. In particular, a barrier of the hole injection from the first layer into the second layer corresponds to an energy obtained by subtracting the ionization potential of the first layer from the ionization potential of the second layer.

As illustrated in FIG. 9, the ionization potential IPB of the blue light-emitting layer 13B is larger than the ionization potential IPR of the red light-emitting layer 13R and the ionization potential IPG of the green light-emitting layer 13G. Thus, a barrier of the hole injection from the hole transport layer 12 into the blue light-emitting layer 13B is larger than a barrier of the hole injection from the hole transport layer 12 into the red light-emitting layer 13R and a barrier of the hole injection from the hole transport layer 12 into the green light-emitting layer 13G. As the particle diameter is smaller, the band gap becomes larger. As illustrated in FIG. 10, the band gap of the blue light-emitting layer 13B is larger than the band gap of the green light-emitting layer 13G, and the band gap of the green light-emitting layer 13G is larger than the band gap of the red light-emitting layer 13R. Thus, as described above, as the emission wavelength becomes shorter, it becomes more difficult for holes to be injected into the light-emitting layer, resulting in a state of further excess of electrons.

Thus, in the present embodiment, as described above, the ratio of the cross-sectional area of the second material to the cross-sectional area of the first material in the electron transport layer 14B is larger than the ratio of the cross-sectional area of the second material to the cross-sectional area of the first material in the electron transport layer 14G. In addition, the ratio of the cross-sectional area of the second material to the cross-sectional area of the first material in the electron transport layer 14B is larger than the ratio of the cross-sectional area of the second material to the cross-sectional area of the first material in the electron transport layer 14R. Thus, an effect of suppressing electrons can be increased in the blue light-emitting element 1B than in the green light-emitting element 1G and the red light-emitting element 1R.

In addition, in the present embodiment, the ratio of the cross-sectional area of the second material to the cross-sectional area of the first material in the electron transport layer 14G is larger than the ratio of the cross-sectional area of the second material to the cross-sectional area of the first material in the electron transport layer 14R. Thus, the effect of suppressing electrons can be increased in the green light-emitting element 1G according to the present embodiment than in the red light-emitting element 1R.

In this way, by changing the ratio of the cross-sectional area of the second material to the cross-sectional area of the first material to increase the effect of suppressing electrons, the carrier balance can be adjusted and the drive voltage can be further reduced.

In FIG. 10, the electron affinity of the red light-emitting layer 13R is EAR, the electron affinity of the green light-emitting layer 13G is EAG, and the electron affinity of the blue light-emitting layer 13B is EAB. As illustrated in FIG. 10, in the present embodiment, the electron affinity EAB of the blue light-emitting layer 13B is smaller than the electron affinity EAG of the green light-emitting layer 13G, and the electron affinity EAG of the green light-emitting layer 13G is smaller than the electron affinity EAR of the red light-emitting layer 13R.

Thus, a barrier of the electron injection from a second material portion 31B in the electron transport layer 14B into the blue light-emitting layer 13B is larger than a barrier of the electron injection from a second material portion 31G in the electron transport layer 14G into the green light-emitting layer 13G. A barrier of the electron injection from the second material portion 31G of the electron transport layer 14G into the green light-emitting layer 13G is larger than the barrier of electron injection from a second material portion 31R of the electron transport layer 14R into the red light-emitting layer 13R.

Thus, as illustrated in FIG. 10, it is assumed that the electron transport layer 14R, the electron transport layer 14G, and the electron transport layer 14B have the same configuration as each other and use the same material as each other. In this case, the drive voltage is higher in the green light-emitting element 1G than in the red light-emitting element 1R, and the drive voltage is higher in the blue light-emitting element 1B than in the green light-emitting element 1G. FIG. 10 illustrates a case where the electron affinity EAR of the red light-emitting layer 13R, the electron affinity EAG of the green light-emitting layer 13G, and the electron affinity EAB of the blue light-emitting layer 13B are larger than the electron affinity EA3 of the second material portion 31. However, in the electron affinity EA3 of the second material portion 31, a case where various materials are used is assumed. For example, the electron affinity EAR of the red light-emitting layer 13R, the electron affinity EAG of the green light-emitting layer 13G, and the electron affinity EAB of the blue light-emitting layer 13B may be smaller than the electron affinity EA3 of the second material portion 31. Here, a case where the electron affinity of the light-emitting layer is larger than the electron affinity EA3 of the second material portion 31 is described as an example.

In this case, in order to further reduce the voltage applied to the display device 50, it is desirable to further reduce the drive voltage of the blue light-emitting layer 13B. In the present embodiment, the above-described second material portion 31B is provided on a surface of a nanoparticle 30B as described above. Thus, the display device 50 can reduce the barrier of the electron injection from the second material portion 31B of the electron transport layer 14B into the blue light-emitting layer 13B while suppressing the electron injection in the blue light-emitting element 1B as described above, thereby reducing the drive voltage of the blue light-emitting element 1B.

In addition, the red light-emitting layer 13R, the green light-emitting layer 13G, and the blue light-emitting layer 13B according to the present embodiment include the inorganic matrix material 41 that fills spaces between the quantum dots 40s. Thus, for the above-described reason, the display device 50 can reduce the excessive electrons in each light-emitting layer while reducing the drive voltage of each light-emitting element. In particular, the red light-emitting layer 13R, the green light-emitting layer 13G, and the blue light-emitting layer 13B according to the present embodiment include the inorganic matrix material 41 having the same composition as the second material. Thus, for the reason described above, the display device 50 can reduce the resistance between the electron transport layer and the light-emitting layer in each light-emitting element and can further reduce the drive voltage of each light-emitting element.

According to the investigation by the inventors of the present application, for example, in the present embodiment, the second material portion 31B made of the inorganic second material having the electron transport ability lower than the first material is provided on the surface of the nanoparticle 30B made of the first material.

Thus, in the present embodiment, even when the light-emitting material without using cadmium and emitting blue light is used, the drive voltage of the blue light-emitting element 1B can be reduced.

In the above-described step S7, magnesium acetate tetrahydrate is added so as to be 50 mol % with respect to the solute of the first solution. Thus, it was confirmed that the drive voltage can be further reduced as compared with the case where magnesium acetate tetrahydrate is added so as to be 30 mol % with respect to the solute of the first solution.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode;
a cathode;
a light-emitting layer between the anode and the cathode; and
an intervening layer between the light-emitting layer and the cathode,
wherein the light-emitting layer includes
a plurality of quantum dots and
an inorganic matrix material that fills spaces between the plurality of quantum dots, and
the intervening layer includes
at least one nanoparticle made of a first material including a metal oxide, and
a second material portion formed on at least part of a surface of the nanoparticle and made of an inorganic second material having an electron transport ability lower than that of the first material.

2. A light-emitting element comprising:
an anode;
a cathode;
a light-emitting layer between the anode and the cathode; and
an intervening layer between the light-emitting layer and the cathode,
wherein the light-emitting layer includes
a plurality of quantum dots and
an inorganic matrix material that fills spaces between the plurality of quantum dots, and
the intervening layer includes
at least one nanoparticle made of a first material including at least one selected from the group consisting of zinc oxide, magnesium zinc oxide, lithium zinc oxide, titanium oxide, and
strontium titanium oxide, and
a second material portion formed on at least part of a surface of the nanoparticle and made of a second material including at least one selected from the group consisting of magnesium oxide, zirconium oxide, aluminum oxide, yttrium oxide, silicon oxide, zinc sulfide, magnesium zinc sulfide, and strontium sulfide.

3. A light-emitting element comprising:
an anode;
a cathode;
a light-emitting layer between the anode and the cathode; and
an intervening layer between the light-emitting layer and the cathode,
wherein the light-emitting layer is formed by a method including
synthesizing a quantum dot solution including a plurality of quantum dots and an inorganic precursor,
applying the quantum dot solution, and
filling spaces between the plurality of quantum dots with an inorganic matrix material by modifying the inorganic precursor into the inorganic matrix material in the applied quantum dot solution, and
the intervening layer is formed by a method including
synthesizing a first solution including at least one nanoparticle made of a first material,
synthesizing a second solution by adding a second material different from the first material to the first solution,
forming a second material portion made of the second material on at least part of a surface of the nanoparticle by an ultrasonic treatment on the second solution, and
applying the second solution including at least one nanoparticle on which the second material portion is formed.

4. The light-emitting element according to claim 1,
wherein the inorganic matrix material and the second material have the same composition.

5. The light-emitting element according to claim 4,
wherein the inorganic matrix material and the second material include the same metal sulfide.

6. The light-emitting element according to claim 5,
wherein the same metal sulfide is a zinc sulfide-based material.

7. The light-emitting element according to claim 1,
wherein the inorganic matrix material and the second material include the same metal oxide.

8. The light-emitting element according to claim 7,
wherein same metal oxide is silicon oxide.

9. The light-emitting element according to claim 7,
wherein the first material includes magnesium zinc oxide.

10. The light-emitting element according to claim 9,
wherein the inorganic matrix material and the second material include magnesium oxide.

11. (canceled)

12. The light-emitting element according to claim 1,
wherein the second material has an electron affinity lower than that of the first material.

13. The light-emitting element according to claim 1,
wherein the light-emitting layer includes a light-emitting material in which a ratio of cadmium atoms in all atoms is 0.01 wt % or less.

14. The light-emitting element according to claim 1, further comprising:
a hole transport layer including an inorganic material between the anode and the light-emitting layer.

15. The light-emitting element according to claim 1, further comprising:
a hole transport layer including an organic material between the anode and the light-emitting layer; and
a hole injection layer including an inorganic material between the anode and the hole transport layer.

16. The light-emitting element according to claim 1,
wherein the second material portion covers 10% or more of an outer periphery of the nanoparticle in a cross section of the nanoparticle.

17. The light-emitting element according to claim 1,
wherein the second material portion is located in island shapes on an outer periphery of the nanoparticle in a cross section of the nanoparticle.

18. The light-emitting element according to claim 17,
wherein the second material portion covers 90% or less of an outer periphery of the nanoparticle in a cross section of the nanoparticle.

19. A display device comprising:
a substrate; and
a red light-emitting element, a green light-emitting element, and a blue light-emitting element on the substrate,
wherein at least one of the red light-emitting element, the green light-emitting element, and the blue light-emitting element is the light-emitting element according to claim 1.

20. A display device comprising:
a substrate; and
a red light-emitting element, a green light-emitting element, and a blue light-emitting element on the substrate,
wherein at least two of the red light-emitting element, the green light-emitting element, and the blue light-emitting element are the light-emitting elements according to claim 1, and
in any two light-emitting elements of the at least two light-emitting elements, when a light-emitting element having a shorter emission wavelength is a short-wavelength element and a light-emitting element having a longer emission wavelength is a long-wavelength element, a ratio of a cross-sectional area of the second material to a cross-sectional area of the first material in a cross section of the intervening layer is smaller in the long-wavelength element than in the short-wavelength element.
